(19) United States
(12) Patent Application Publication
(10) Pub. No.: US 2026/0149297 A1
(43) Pub. Date: May 28, 2026

(54) VACUUM CLEANER INCLUDING A RECHARGEABLE BATTERY AND CONTROL METHOD THEREOF

(71) Applicant: SAMSUNG ELECTRONICS CO., LTD., Suwon-si (KR)

(72) Inventors: Seongu LEE, Suwon-si (KR); Daesung KANG, Suwon-si (KR); Kyounghwan SON, Suwon-si (KR); Ahyoung LEE, Suwon-si (KR); Yoonkyung CHO, Suwon-si (KR)

(73) Assignee: SAMSUNG ELECTRONICS CO., LTD., Suwon-si (KR)

(21) Appl. No.: 19/371,477

(22) Filed: Oct. 28, 2025

Related U.S. Application Data
(63) Continuation of application No. PCT/KR2025/014103, filed on Sep. 10, 2025.

(30) Foreign Application Priority Data
Nov. 26, 2024 (KR) 10-2024-0140665

(51) Int. Cl. H02J 7/00; A47L 9/00; A47L 9/28; G01R 31/3835

(52) U.S. Cl. CPC H02J 7/933; A47L 9/0063; A47L 9/2805; A47L 9/2836; A47L 9/2857; A47L 9/2873; A47L 9/2884; A47L 9/2894; G01R 31/3835; A47L 2201/022

(57) ABSTRACT

A vacuum cleaner includes: memory storing instructions; a power part including a rechargeable battery; a suction motor configured to be driven by power supplied by the power part to suction debris; a debris container configured to store the debris that is suctioned by the suction motor; a charging terminal configured to be connectable to an external charging device that is configured to charge the rechargeable battery; and at least one processor including processing circuitry, where the instructions, when executed individually or collectively by the at least one processor, cause the vacuum cleaner to: perform a charging function in a first mode by supplying a battery current of a threshold strength to the rechargeable battery, obtain, in a state of performing the charging function in the first mode, a first voltage of the charging terminal of the vacuum cleaner.

### CROSS-REFERENCE TO RELATED APPLICATION

This application is a bypass continuation of International Application No. PCT/KR2025/014103, filed on Sep. 10, 2025, which is based on and claims priority to Korean Patent Application No. 10-2024-0170665, filed on Nov. 26, 2024, in the Korean Intellectual Property Office, the disclosures of which are incorporated by reference herein in their entireties.

### BACKGROUND

### 1. Field

The disclosure relates to a vacuum cleaner including a rechargeable battery and a control method thereof, and more particularly, to a vacuum cleaner which monitors for problems in charging which may occur while supplying power to a battery, and a control method thereof.

### 2. Description of Related Art

Among devices that operate wirelessly, a battery for recharging may be included. The battery for recharging may be charged in advance, and an operation may be performed wirelessly using power supplied from the recharged battery. A charging device may be used separately to recharge the battery. A vacuum cleaner including a battery and a charging device which supplies power for recharging the vacuum cleaner may be present separately.

If the vacuum cleaner and the charging device are in contact with each other, power may be supplied from the charging device to the vacuum cleaner. If contact is not made normally, charging efficiency may deteriorate. In addition, a problem of heat generating at a contact terminal may occur.

Charging may not be carried out normally in various situations such as modification of the contact terminal, assembly variation, misassembly, abnormal docking, vibration, chattering, and a foreign substance being present at a contacting part.

### SUMMARY

Provided are a vacuum cleaner which identifies charging error by analyzing voltage difference of a vacuum cleaner and a charging device while performing a charging function and a control method thereof.

Additional aspects will be set forth in part in the description which follows and, in part, will be apparent from the description, or may be learned by practice of the presented embodiments.

According to an aspect of the disclosure, a vacuum cleaner may include: memory storing instructions; a power part including a rechargeable battery; a suction motor configured to be driven by power supplied by the power part to suction debris; a debris container configured to store the debris that is suctioned by the suction motor; a charging terminal configured to be connectable to an external charging device that is configured to charge the rechargeable battery; and at least one processor including processing circuitry, where the instructions, when executed individually or collectively by the at least one processor, cause the vacuum cleaner to: perform a charging function in a first mode by supplying a battery current of a threshold strength to the rechargeable battery, obtain, in a state of performing the charging function in the first mode, a first voltage of the charging terminal of the vacuum cleaner and a second voltage of a charging terminal of the external charging device, identify whether a charging error has occurred based on the first voltage and the second voltage, based on identifying the charging error has not occurred, obtain a battery voltage of the rechargeable battery in the state of performing the charging function in the first mode, and based on the battery voltage being greater than or equal to a threshold value, performing the charging function in a second mode by maintaining the battery voltage within a threshold range that corresponds to the threshold value.

The instructions, when executed by the at least one processor individually or collectively, may cause the vacuum cleaner to: based on identifying the charging error has occurred, stop performing the charging function in the first mode, where the charging error includes an error due to a charging abnormality between the charging terminal of the vacuum cleaner and the charging terminal of the external charging device.

The instructions, when executed individually or collectively by the at least one processor, may cause the vacuum cleaner to: obtain a difference value between the first voltage and the second voltage, and identify whether the charging error has occurred based on the difference value.

The instructions, when executed by the at least one processor individually or collectively, may cause the vacuum cleaner to: continue performing the charging function in the first mode based on the difference value being less than or equal to a first threshold value, and based on the difference value exceeding a second threshold value which is greater than the first threshold value, identify that the charging error has occurred.

The instructions, when executed by the at least one processor individually or collectively, may cause the vacuum cleaner to: based on the difference value exceeding the first threshold value and being less than or equal to the second threshold value, identify whether the charging error has occurred by re-obtaining the first voltage and the second voltage.

The instructions, when executed by the at least one processor individually or collectively, may cause the vacuum cleaner to: based on identifying the charging error has occurred, stop performing the charging function in the first mode by controlling a switch of the power part to be an off state.

The vacuum cleaner may further include: a display; and a speaker, where the instructions, when executed by the at least one processor individually or collectively, cause the vacuum cleaner to: based on identifying the charging error has occurred, control the display to display an error user interface (UI) indicating the charging error, or control the speaker to output a sound corresponding to the error UI.

The vacuum cleaner may further include: a communication interface, where the instructions, when executed by the at least one processor individually or collectively, cause the vacuum cleaner to: activate the communication interface based on the charging terminal of the vacuum cleaner being in contact with the charging terminal of the external charging device, request, through the communication interface, a response from the external charging device, identify that an error has occurred based on a response signal not being received from the external charging device through the communication interface, and output an error user interface (UI) to indicate that the error has occurred.

The instructions, when executed by the at least one processor individually or collectively, cause the vacuum cleaner to: perform the charging function in the first mode based on the response signal being received from the external charging device through the communication interface.

The first mode corresponds to a constant current (CC) mode configured to maintain a strength of the battery current at the threshold strength, where the second mode corresponds to a constant voltage (CV) mode configured to maintain the battery voltage within the threshold range based on the threshold value.

According to an aspect of the disclosure, provided is a control method of a vacuum cleaner including a power part which includes a rechargeable battery, a suction motor configured to be driven by power supplied by the power part to suction debris, a debris container configured to store the debris that is suctioned by the suction motor, and a charging terminal configured to be connectable to an external charging device that is configured to charge the rechargeable battery, the control method may include: performing a charging function in a first mode by supplying a battery current of a threshold strength to the rechargeable battery; obtaining, in a state of performing the charging function in the first mode, a first voltage of the charging terminal of the vacuum cleaner and a second voltage of a charging terminal of the external charging device; identifying whether a charging error has occurred based on the first voltage and the second voltage; based on identifying that the charging error has occurred, stop performing the charging function in the first mode; based on identifying the charging error has not occurred, obtaining a battery voltage of the rechargeable battery in the state of performing the charging function in the first mode; and based on the battery voltage being greater than or equal to a threshold value, performing the charging function in a second mode by maintaining the battery voltage within a threshold range that corresponds to the threshold value.

The charging error may include an error due to a charging abnormality between the charging terminal of the vacuum cleaner and the charging terminal of the external charging device.

The identifying whether the charging error has occurred may include: obtaining a difference value between the first voltage and the second voltage, and identifying whether the charging error has occurred based on the difference value.

The identifying whether the charging error has occurred may include: continue performing the charging function in the first mode based on the difference value being less than or equal to a first threshold value, and based on the difference value exceeding a second threshold value which is greater than the first threshold value, identifying that the charging error has occurred.

The identifying whether the charging error has occurred may further include: based on the difference value exceeding the first threshold value and being less than or equal to the second threshold value, identifying whether the charging error has occurred by re-obtaining the first voltage and the second voltage.

According to an aspect of the disclosure, an electronic device may include: memory storing instructions; a power part including a rechargeable battery; a charging terminal configured to be connectable to an external charging device that is configured to charge the rechargeable battery; and at least one processor including processing circuitry, where the instructions, when executed by the at least one processor individually or collectively, cause the electronic device to: perform a charging function in a first mode by supplying a battery current of a threshold strength to the rechargeable battery, obtain, in a state of performing the charging function in the first mode, a first voltage of the charging terminal of the electronic device and a second voltage of a charging terminal of the external charging device, identify whether a charging error has occurred based on the first voltage and the second voltage, based on identifying the charging error has occurred, obtain a battery voltage of the rechargeable battery in the state of performing the charging function in the first mode, and based on the battery voltage being greater than or equal to a threshold value, performing the charging function in a second mode by maintaining the battery voltage within a threshold range that corresponds to the threshold value.

The instructions, when executed by the at least one processor individually or collectively, may cause the electronic device to: based on identifying the charging error has occurred, stop performing the charging function in the first mode, where the charging error includes an error due to a charging abnormality between the charging terminal of the electronic device and the charging terminal of the external charging device.

The instructions, when executed by the at least one processor individually or collectively, may cause the electronic device to: obtain a difference value between the first voltage and the second voltage, and identify whether the charging error has occurred based on the difference value.

The instructions, when executed by the at least one processor individually or collectively, may cause the electronic device to: continue performing the charging function in the first mode based on the difference value being less than or equal to a first threshold value, and based on the difference value exceeding a second threshold value which is greater than the first threshold value, identify that the charging error has occurred.

The instructions, when executed by the at least one processor individually or collectively, cause the electronic device to: based on the difference value exceeding the first threshold value and being less than or equal to the second threshold value, identify whether the charging error has occurred by re-obtaining the first voltage and the second voltage.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a diagram illustrating a vacuum cleaner and a charging device according to an embodiment;

FIG. 2 is a block diagram illustrating a vacuum cleaner according to an embodiment;

FIG. 3 is a block diagram illustrating a detailed configuration of the vacuum cleaner in FIG. 2 according to an embodiment;

FIG. 4 is a diagram illustrating a mobile vacuum cleaner according to an embodiment;

FIG. 5 is a diagram illustrating a structure of a vacuum cleaner and a charging device according to an embodiment;

FIG. 6 is a diagram illustrating a charging operation according to an embodiment;

FIG. 7 is a diagram illustrating the charging operation of FIG. 6 in detail according to an embodiment;

FIG. 8 is a diagram illustrating an operation for checking a charging error according to an embodiment;

FIG. 9 is a diagram illustrating an operation for checking battery current according to an embodiment;

FIG. 10 is a diagram illustrating an operation for checking voltage difference according to an embodiment;

FIG. 11 is a diagram illustrating an operation for calculating a number of additional inspections according to an embodiment;

FIG. 12 is a diagram illustrating an operation for requesting sensing data to a charging device according to an embodiment;

FIG. 13 is a diagram illustrating an operation for calculating voltage difference according to an embodiment;

FIG. 14 is a diagram illustrating battery current, battery voltage, and equivalent resistance according to an embodiment;

FIG. 15 is a diagram illustrating battery current, battery voltage, and equivalent resistance according to an embodiment;

FIG. 16 is a diagram illustrating battery temperature, and charge amount according to an embodiment;

FIG. 17 is a diagram illustrating an operation for analyzing voltage difference according to an embodiment;

FIG. 18 is a diagram illustrating analysis results corresponding to voltage differences according to an embodiment;

FIG. 19 is a diagram illustrating an operation for when an error occurs according to an embodiment;

FIG. 20 is a diagram illustrating an error UI being provided to a terminal device according to an embodiment;

FIG. 21 is a diagram illustrating a first error UI according to an embodiment;

FIG. 22 is a diagram illustrating a second error UI according to an embodiment; and

FIG. 23 is a diagram illustrating a control method of an electronic device according to an embodiment.

### DETAILED DESCRIPTION

The disclosure will be described in detail below with reference to the accompanying drawings.

Terms used in describing embodiments of the disclosure are general terms selected that are currently widely used considering their function herein. However, the terms may change depending on intention, legal or technical interpretation, emergence of new technologies, and the like of those skilled in the related art. Further, in certain cases, there may be terms arbitrarily selected, and in this case, the meaning of the term will be disclosed in greater detail in the relevant description. Accordingly, the terms used herein are not to be understood simply as its designation but based on the meaning of the term and the overall context of the disclosure.

In the disclosure, expressions such as “comprise”, “may comprise”, “have”, “may have”, “include”, and “may include” are used to designate a presence of a corresponding characteristic (e.g., elements such as numerical value, function, operation, or component), and not to preclude a presence or a possibility of additional characteristics.

The expression at least one of A and/or B is to be understood as indicating any one of “A” or “B” or “A and B”.

Expressions such as “1st”, “2nd”, “first”, or “second” used in the disclosure may limit various elements regardless of order and/or importance, and may be used merely to distinguish one element from another element and not limit the relevant element.

When a certain element (e.g., a first element) is indicated as being “(operatively or communicatively) coupled with/to” or “connected to” another element (e.g., a second element), it may be understood as the certain element being directly coupled with/to the another element or as being coupled through other element (e.g., a third element).

A singular expression includes a plural expression, unless otherwise specified. It is to be understood that the terms such as “configured,” “include”, “comprise” or the like are used herein to designate a presence of a characteristic, number, step, operation, element, component, or a combination thereof, and not to preclude a presence or a possibility of adding one or more of other characteristics, numbers, steps, operations, elements, components or a combination thereof.

The term “module” or “part” used herein perform at least one function or operation, and may be implemented with hardware or software, or implemented with a combination of hardware and software. In addition, a plurality of “modules” or a plurality of “parts”, except for a “module” or a “part” which needs to be implemented with a specific hardware, may be integrated in at least one module and implemented as at least one processor.

In the disclosure, the term “user” may refer to a person using an electronic device or a device (e.g., artificial intelligence electronic device) using an electronic device.

An embodiment of the disclosure will be described in greater detail below with reference to the accompanied drawings.

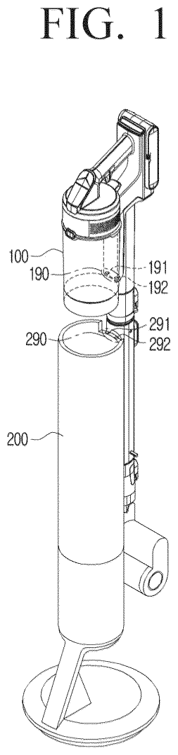

FIG. 1 is a diagram illustrating a vacuum cleaner 100 and a charging device 200 according to an embodiment.

Referring to FIG. 1, the vacuum cleaner 100 may be a device that includes a battery. The vacuum cleaner 100 may perform electric operations wirelessly using the charged battery. The vacuum cleaner 100 may perform a determined function wirelessly without being connected to a plug via wire.

The vacuum cleaner 100 may include a charging terminal 190. The charging terminal 190 may include a first terminal 191 and a second terminal 192. The first terminal 191 may be a negative electrode terminal of the vacuum cleaner 100. The second terminal 192 may be a positive electrode terminal of the vacuum cleaner 100.

The charging device 200 may include a charging terminal 290. The charging terminal 290 may include a first terminal 291 and a second terminal 292. The first terminal 291 may be a negative electrode terminal of the charging device 200. The second terminal 292 may be a positive electrode terminal of the charging device 200.

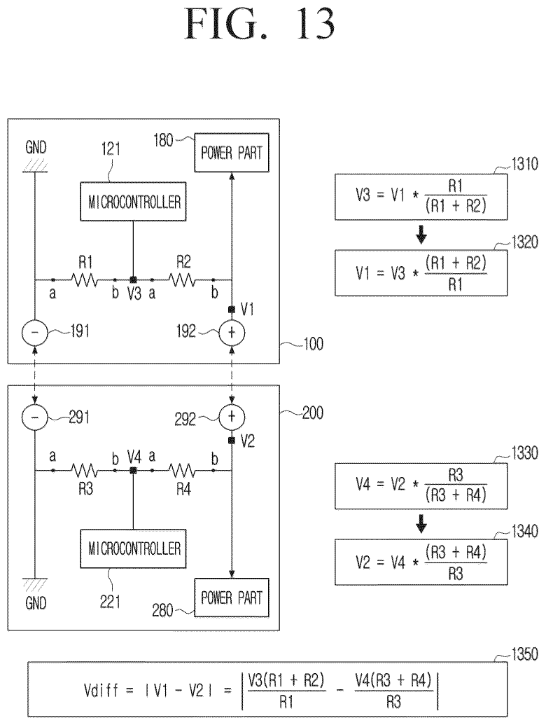

Descriptions associated with each terminal will be described in FIG. 13.

The vacuum cleaner 100 and the charging device 200 may be contacted based on the charging terminals 190 and 290. It may be assumed that the charging device 200 is disposed in a fixed state, but this is merely an example, and the disclosure is not limited thereto. The vacuum cleaner 100 may be contacted with the charging device 200 through the charging terminals 190 and 290.

If the vacuum cleaner 100 and the charging device 200 are contacted, the charging device 200 may supply charging power to the vacuum cleaner 100. The vacuum cleaner 100 may charge the battery included in the vacuum cleaner 100 based on power received from the charging device 200.

According to an embodiment, the vacuum cleaner 100 may be a device that performs a function of suctioning foreign materials. The vacuum cleaner 100 may be a vacuum cleaner that performs a cleaning function.

In an example, the vacuum cleaner 100 may be a handy-type (or handheld-type) vacuum cleaner operated by a user. The handy-type vacuum cleaner may be a vacuum cleaner in a form which can be easily gripped with one hand by the user.

In an example, the vacuum cleaner 100 may be a stick-type vacuum cleaner. The stick-type vacuum cleaner may be a vacuum cleaner having a stick shaped main body and a handle.

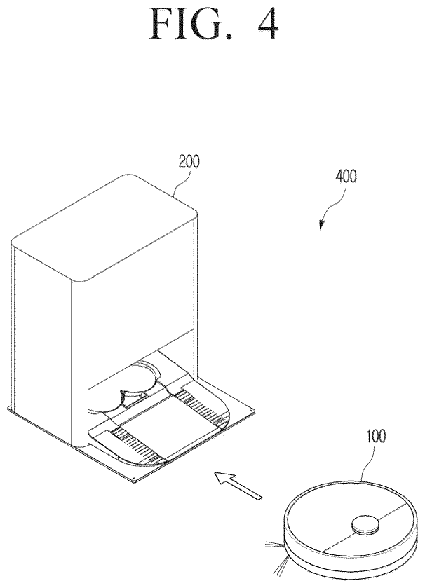

In an example, the vacuum cleaner 100 may be a mobile robot which is moved automatically. Descriptions associated therewith will be described in FIG. 4.

In an example, the vacuum cleaner 100 may be a wireless vacuum cleaner.

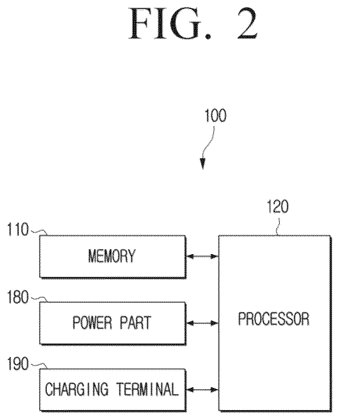

FIG. 2 is a block diagram illustrating the vacuum cleaner 100 according to an embodiment.

Referring to FIG. 2, the vacuum cleaner 100 may include a memory 110 which stores instructions, and a power part 180 which includes a rechargeable battery 182.

A suction motor 175 driven by power supplied through the power part, a debris container for storing debris suctioned according to rotation of the suction motor, the charging terminal 190 which is connected with a charging device 200, and at least one processor 120 which includes processing circuitry may be included.

The debris container may be described as a debris storage box or a foreign material storage pack.

The at least one processor 120 may perform an electric operation using the battery 182. In an example, the at least one processor 120 may control the suction motor 175 based on power supplied from the battery 182.

The vacuum cleaner 100 may charge the battery 182 through a charging function. The at least one processor 120 may perform the charging function for charging the battery 182.

The vacuum cleaner 100 may be connected with the charging device 200. The at least one processor 120 may receive supply of external power from the charging device 200. The charging device 200 may be described as a charging station.

A plurality of modes for charging the battery 182 may be provided. The plurality of modes may include a first mode and a second mode.

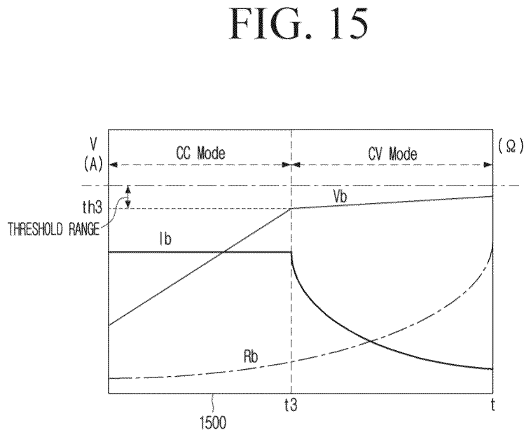

In an example, the first mode may be a constant current (CC) mode for maintaining a strength of battery current (Ib) to a threshold strength. In an example, the second mode may be a constant voltage (CV) mode for maintaining a battery voltage (Vb) to a threshold value (a third threshold value). Descriptions associated with the first mode and the second mode will be described in FIG. 15. The vacuum cleaner 100 may control a battery state to the first mode or the second mode.

An operation for maintaining the battery current (Ib) to the threshold strength may indicate an operation for maintaining the battery current (Ib) to be present within a threshold range. The vacuum cleaner 100 may control the power part 180 for the battery current (Ib) to be present within the threshold range based on the threshold strength.

An operation for maintaining the battery voltage (Vb) to the threshold value may indicate an operation for maintaining the battery voltage (Vb) to be present within the threshold range. The vacuum cleaner 100 may control the power part 180 for the battery voltage (Vb) to be present within the threshold range based on the threshold value (third threshold value).

In an example, if the third threshold value of the battery voltage (Vb) is th3 (V), the threshold range may be between th3 (V) and +a (V).

In an example, if the third threshold value of the battery voltage (Vb) is th3 (V), the threshold range may be th3+b (V) and th3−b (V).

The threshold range may be described as a threshold ratio. In an example, if the third threshold value of the battery voltage (Vb) is th3 (V), the threshold ratio may be +c % (V) and −d %(V). The threshold ratio may be changed by a user setting.

Numbers such as third threshold value (th3), a, b, c, d, and the like may be changed according to the user setting.

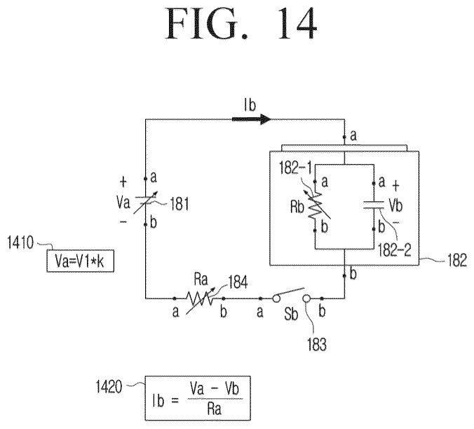

The battery current (Ib) may be current that is supplied to the battery 182. The battery voltage (Vb) may indicate an internal voltage of the battery 182. A circuit diagram associated therewith will be described in FIG. 14.

If the vacuum cleaner 100 is contacted with the charging device 200, the at least one processor 120 may charge the battery 182.

The at least one processor 120 may operate in the first mode performing the charging function by supplying the battery current (Ib) of threshold strength to the battery 182.

While operating in the first mode, the at least one processor 120 may obtain first voltage (V1) corresponding to the charging terminal 190 of the vacuum cleaner 100 and second voltage (V2) corresponding to the charging terminal 290 of the charging device 200.

The first voltage (V1) may be voltage that is applied to the charging terminal 190 of the vacuum cleaner 100. The second voltage (V2) may be voltage that is applied to the charging terminal 290 of the charging device 200. Descriptions associated with the first voltage (V1) and the second voltage (V2) will be described in FIG. 13.

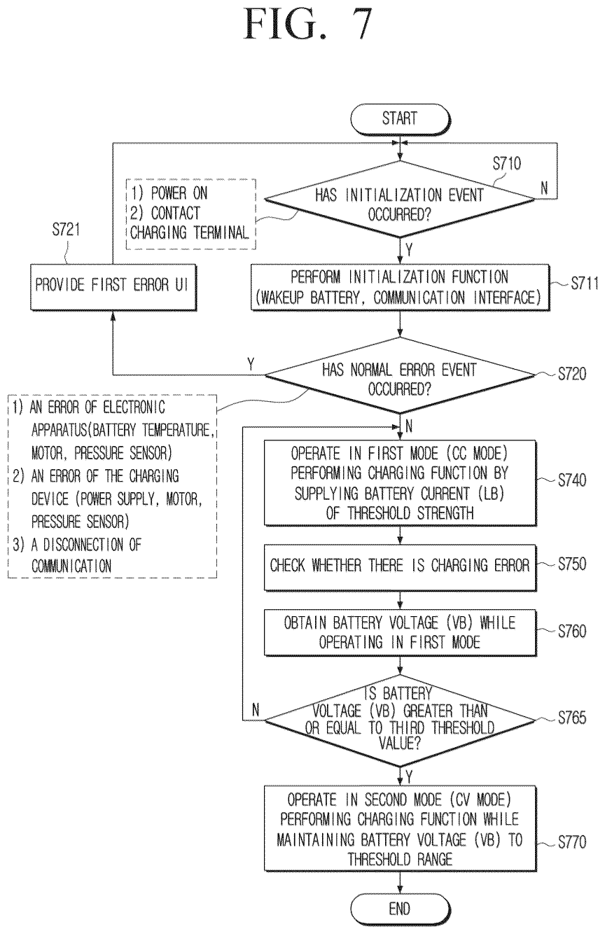

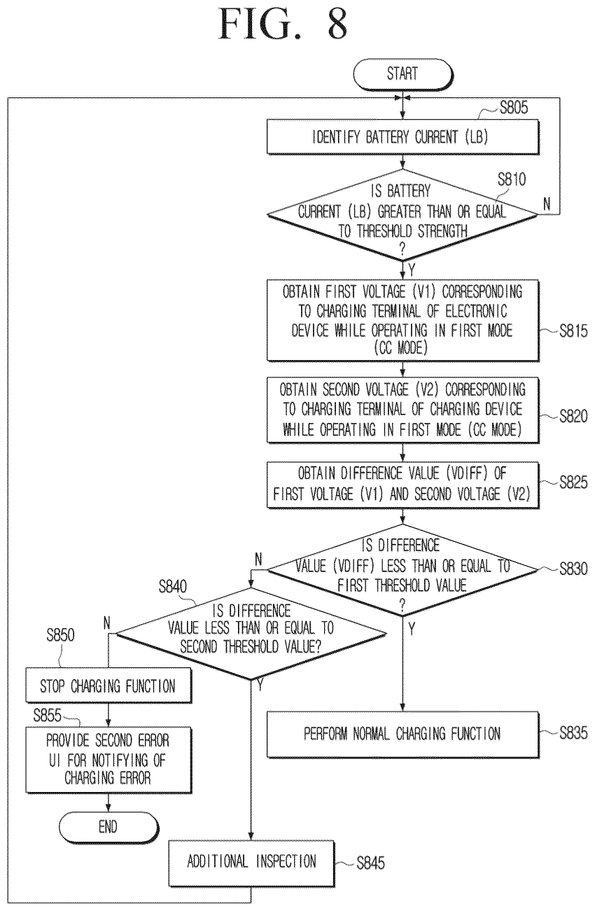

The at least one processor 120 may identify an occurrence of charging error based on the first voltage (V1) and the second voltage (V2). An operation for identifying the occurrence of charging error may correspond to step S750 in FIG. 7. A specific operation associated therewith will be described in FIG. 8.

The charging error may include an error due to an abnormal charging of the charging terminal 190 of the vacuum cleaner 100 and the charging terminal 290 of the charging device 200. In an example, the abnormal charging may include an error of a coupling position of the charging terminals 190 and 290 not matching. When a charging error occurs, the charging function may not be normally performed. A space between the vacuum cleaner 100 and the charging device 200 may be recognized as resistance and charging efficiency may deteriorate. If the charging error occurs, components associated with charging (e.g., charging terminal 190 and charging terminal 290) may be damaged or modified. If the charging error occurs, fire (or ignition) may occur under a specific condition. Damage to a product itself or injury to a user may occur due to the fire.

The at least one processor 120 may obtain a difference value (Vdiff) of the first voltage (V1) and the second voltage (V2). The at least one processor 120 may identify the occurrence of charging error based on the difference value (Vdiff).

If the difference value (Vdiff) is less than or equal to a first threshold value, the at least one processor 120 may continue to operate in the first mode.

If the difference value (Vdiff) exceeds a second threshold value, the at least one processor 120 may identify that the charging error has occurred.

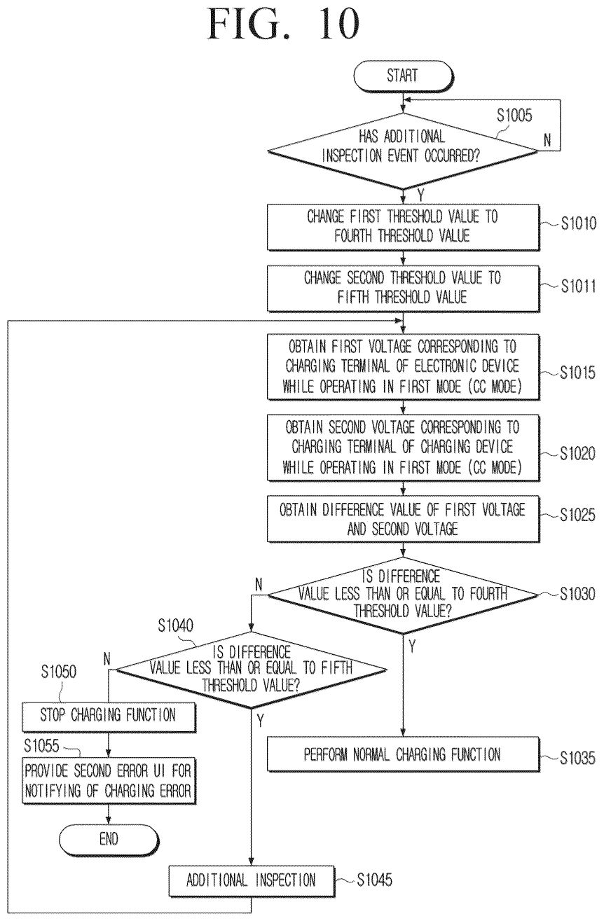

If the difference value (Vdiff) exceeds the first threshold value and is less than or equal to the second threshold value, the at least one processor 120 may identify the occurrence of charging error by re-obtaining the first voltage (V1) and the second voltage (V2). An operation for re-obtaining the first voltage (V1) and the second voltage (V2) may be included in an operation for additional inspection. Descriptions associated therewith may correspond to operation S845 in FIG. 8. Additional descriptions associated therewith will be described in FIG. 10.

If the charging error occurs, the at least one processor 120 may stop the charging function in the first mode. An operation for stopping the charging function may correspond to operation S850 in FIG. 8.

In an example, if the charging error occurs, the charging function in the first mode may be stopped by controlling a switch 183 included in the power part 180 to an off state.

If the charging error occurs, the at least one processor 120 may provide an error user interface (UI) (a second error UI) indicating a charging error. The charging error occurring may mean that a difference of voltage (second voltage (V2)) supplied from the charging device 200 and voltage (first voltage (V1)) received in the vacuum cleaner 100 is significant.

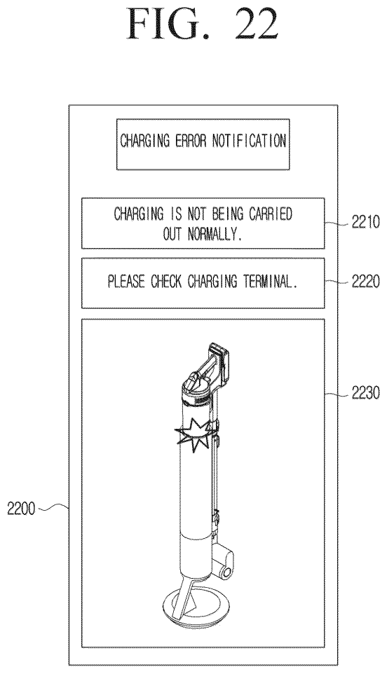

The at least one processor 120 may provide the error UI (second error UI) to warn that the charging function may not be carried out normally. The error UI (second error UI) may be a UI for indicating that an error associated with charging has occurred. Descriptions associated therewith will be described in FIG. 22.

If the charging error does not occur, the at least one processor 120 may obtain battery voltage (Vb) corresponding to the battery 182 while operating in the first mode. If the battery voltage (Vb) is greater than or equal to the threshold value (third threshold value), the at least one processor 120 may operate in the second mode performing the charging function by maintaining the battery voltage (Vb).

The at least one processor 120 may check whether a normal error has occurred prior to performing the charging function in the first mode. The charging error may indicate an error associated with charging and may be obtained based on the difference value (Vdiff). However, the normal error may include an error that is not associated with charging. Descriptions associated therewith will be described in operation S720 in FIG. 7.

The vacuum cleaner 100 may include a communication interface 130. The at least one processor 120 may activate the communication interface 130 when the charging terminal 190 of the vacuum cleaner 100 and the charging terminal 290 of the charging device 200 are contacted.

When the communication interface 130 is activated, the at least one processor 120 may request, through the communication interface 130, a response from the charging device 200. The communication interface 130 may be changed from an inactivated state to an activated state.

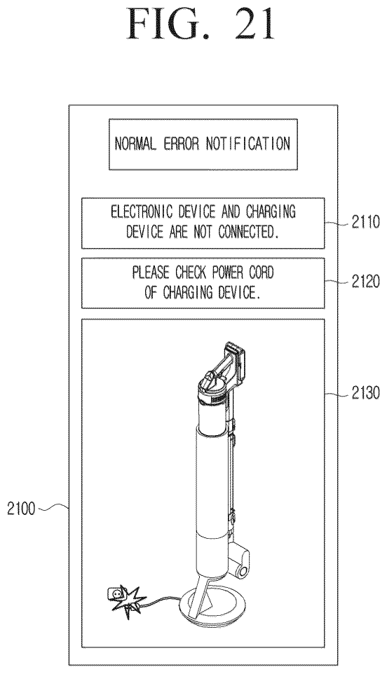

After requesting the response from the charging device 200, the at least one processor 120 may identify that the normal error has occurred if a response signal is not received from the charging device 200 through the communication interface 130. The at least one processor 120 may provide an error UI (a first error UI) indicating that the normal error has occurred. Descriptions associated with the first error UI will be described in FIG. 21.

The at least one processor 120 may perform the charging function in the first mode if the response signal is received from the charging device 200 through the communication interface 130.

If there is a problem with contact between the charging terminal 190 of the vacuum cleaner 100 and the charging terminal 290 of the charging device 200, a problem of heat generating may occur. The vacuum cleaner 100 may accurately determine a contact problem using the difference value (Vdiff). Problems escalating to damage (or corrosion) of the charging terminal may be prevented.

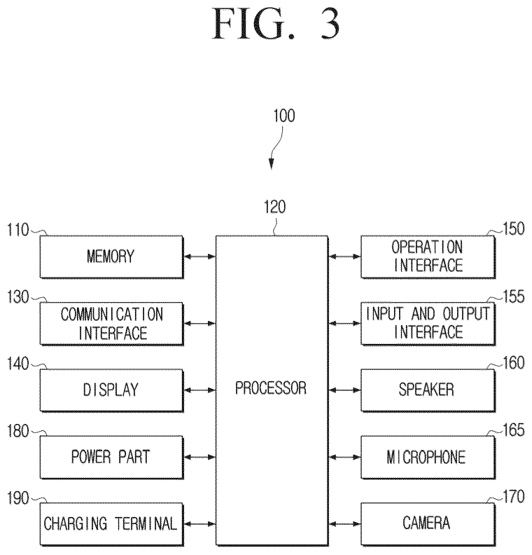

FIG. 3 is a block diagram illustrating a detailed configuration of the vacuum cleaner 100 in FIG. 2 according to an embodiment.

Referring to FIG. 3, the vacuum cleaner 100 may include at least one from among the memory 110, at least one processor 20, the communication interface 130, a display 140, an operation interface 150, an input and output interface 155, a speaker 160, a microphone 165, and a camera 170. The vacuum cleaner 100 may include the power part 180 and the charging terminal 190. Descriptions associated therewith has been described in FIG. 2. Redundant descriptions thereof will be omitted.

The memory 110 may be implemented as an internal memory such as, for example, and without limitation, a read only memory (ROM) (e.g., an electrically erasable programmable read only memory (EEPROM)), a random access memory (RAM), and the like included in the at least one processor 120, or implemented as a memory separate from the at least one processor 120. The memory 110 may be implemented in a form of a memory embedded in the vacuum cleaner 100 according to data storage use, or implemented in a form of a memory attachable to or detachable from the vacuum cleaner 100. For example, data for driving of the vacuum cleaner 100 may be stored in the memory embedded in the vacuum cleaner 100, and data for an expansion function of the vacuum cleaner 100 may be stored in the memory attachable to or detachable from the vacuum cleaner 100.

The memory embedded in the vacuum cleaner 100 may be implemented as at least one from among a volatile memory (e.g., a dynamic RAM (DRAM), a static RAM (SRAM), or a synchronous dynamic RAM (SDRAM)), or a non-volatile memory (e.g., a one time programmable ROM (OTPROM), a programmable ROM (PROM), an erasable and programmable ROM (EPROM), an electrically erasable and programmable ROM (EEPROM), a mask ROM, a flash ROM, a flash memory (e.g., NAND flash or NOR flash), a hard disk drive (HDD) or a solid state drive (SSD)), and the memory attachable to or detachable from the vacuum cleaner 100 may be implemented in a form such as, for example, and without limitation, a memory card (e.g., a compact flash (CF), a secure digital (SD), a micro secure digital (micro-SD), a mini secure digital (mini-SD), an extreme digital (xD), a multi-media card (MMC), etc.), an external memory (e.g., a USB memory) connectable to a USB port, or the like.

The memory 110 may store at least one instruction. The at least one processor 120 may perform various operations based on the instructions stored in the memory 110.

The at least one processor 120 may be implemented as a digital signal processor (DSP) for processing digital signals, a microprocessor, or a time controller (TCON). However, the embodiment is not limited thereto, and may include one or more from among a central processing unit (CPU), a micro controller unit (MCU), a micro processing unit (MPU), a controller, an application processor (AP), a graphics-processing unit (GPU), a communication processor (CP), or Advanced Reduced instruction set computer (RISC) Machines (ARM) processor, or may be defined by a relevant term. The at least one processor 120 may be implemented as a System on Chip (SoC) or a large scale integration (LSI) in which a processing algorithm is embedded, and may be implemented in a form of a field programmable gate array (FPGA). The at least one processor 120 may perform various functions by executing computer executable instructions stored in the memory.

The communication interface 130 may be a configuration for performing communication with external devices of various types according communication methods of various types. The communication interface 130 may include a wireless communication module or a wired communication module. Each communication module may be implemented in at least one hardware chip form.

The wireless communication module may be a module for communicating with an external device via wireless communication. For example, the wireless communication module may include at least one module from among a Wi-Fi module, a Bluetooth module, an infrared communication module, or other communication modules.

The Wi-Fi module and the Bluetooth module may perform communication in a Wi-Fi method and a Bluetooth method, respectively. When using the Wi-Fi module or the Bluetooth module, various connection information such as a service set identifier (SSID) and a session key may first be transmitted and received, and may transmit and receive various information after communicatively connecting using the same.

The infrared communication module may perform communication according to an infrared communication (Infrared Data Association (IrDA)) technology of transmitting data wirelessly in short range by using infrared rays present between visible rays and millimeter waves.

The other communication modules may include at least one communication chip that performs communication according to various wireless communication standards such as, for example, and without limitation, ZigBee, 3rd Generation (3G), 3rd Generation Partnership Project (3GPP), Long Term Evolution (LTE), LTE Advanced (LTE-A), 4th Generation (4G), 5th Generation (5G), and the like, in addition to the above-described communication methods.

The wired communication module may be a module for communicating with an external device via wired communication. For example, the wired communication module may include at least one from among a local area network (LAN) module, an Ethernet module, a pair cable, a coaxial cable, an optical fiber cable, or an ultra wide-band (UWB) module.

According to an embodiment, the communication interface 130 may use the same communication module (e.g., Wi-Fi module) for communicating with an external device such as a remote control device and an external server.

According to an embodiment, the communication interface 130 may use different communication modules for communicating with the external device such as the remote control device and the external server. For example, the communication interface 130 may use at least one from among the Ethernet module or the Wi-Fi module to communicate with the external server, or use the Bluetooth module to communicate with the external device such as the remote control device. However, the above is merely one embodiment, and the communication interface 130 may use at least one communication module from among various communication modules when communicating with a plurality of external devices or external servers.

The display 140 may be implemented as displays of various forms such as, for example, and without limitation, a liquid crystal display (LCD), an organic light emitting diode (OLED) display, a plasma display panel (PDP), and the like. In the display 140, a driving circuit, which may be implemented in a form of an amorphous silicon thin film transistor (a-si TFT), a low temperature poly silicon (LTPS) TFT, an organic TFT (OTFT), or the like, a backlight unit, and the like may be included. The display 140 may be implemented as a touch screen coupled with a touch sensor, a flexible display, a three-dimensional display (3D display), or the like. According to an embodiment of the disclosure, the display 140 may include, not only a display panel that outputs images, but also a bezel that houses the display panel. Specifically, according to an embodiment of the disclosure, the bezel may include a touch sensor for sensing a user interaction.

The operation interface 150 may be implemented as device such as a button, a touch pad, a mouse, and a keyboard, or implemented as a touch screen capable of performing the above-described display function and an operation input function together therewith. The button may be buttons of various types such as a mechanical button, a touch pad, or a wheel which is formed at a random area at a front surface part or a side surface part, a rear surface part, or the like of an exterior of a main body of the vacuum cleaner 100.

The input and output interface 155 may be any one interface from among a High Definition Multimedia Interface (HDMI), a Mobile High-Definition Link (MHL), a Universal Serial Bus (USB), a Display Port (DP), Thunderbolt, a Video Graphics Array (VGA) port, an RGB port, a D-subminiature (D-SUB), or a Digital Visual Interface (DVI). The input and output interface 155 may input and output at least one from among an audio signal and a video signal. According to an embodiment, the input and output interface 155 may include a port which inputs and outputs only audio signals and a port which inputs and outputs only video signals as separate ports, or may be implemented as one port which inputs and outputs both the audio signals and the video signals. The vacuum cleaner 100 may transmit at least one from among the audio signals or the video signals to an external device (e.g., an external display device or an external speaker) through the input and output interface 155. An output port included in the input and output interface 155 may be connected with an external device, and the vacuum cleaner 100 may transmit at least one from among the audio signals and the video signals to the external device through the output port.

The input and output interface 155 may be connected with the communication interface. The input and output interface 155 may transmit information received from an external device to the communication interface or transmit information received through the communication interface to an external device.

The speaker 160 may be an element which outputs not only various audio data, but also various notification sounds, voice messages, or the like.

The microphone 165 may be a configuration for receiving input of a user voice or other sounds and converting to audio data. The microphone 165 may receive the user voice in an activated state. For example, the microphone 165 may be formed as an integrated-type at an upper side or a front surface direction, a side surface direction or the like of the vacuum cleaner 100. The microphone 165 may include various configurations such as, for example, and without limitation, a microphone that collects the user voice in an analog form, an amplifier circuit that amplifies the collected user voice, an A/D converter circuit that samples the amplified user voice and converts to a digital signal, a filter circuit that removes noise components from the converted digital signal, and the like.

The camera 170 may be a configuration for generating a captured image by capturing a subject, and the captured image may be a concept that includes both a moving image and a still image. The camera 170 may obtain an image of at least one external device, and may be implemented with a camera, a lens, an infrared sensor, and the like.

The camera 170 may include a lens and an image sensor. Types of lenses may include a typically generic-purpose lens, a wide-angle lens, a zoom lens, and the like, and the lens may be determined according to a type, a characteristic, use environment and the like of the vacuum cleaner 100. As an image sensor, a Complementary Metal Oxide Semiconductor (CMOS) and a Charge Coupled Device (CCD), and the like may be used.

FIG. 4 is a diagram illustrating a mobile vacuum cleaner 100 according to an embodiment.

Referring to embodiment 400 in FIG. 4, the vacuum cleaner 100 may be a mobile robot. The mobile robot may include a battery. The battery may be charged based on charging power supplied from the charging device 200. The vacuum cleaner 100 may move to perform a function determined wirelessly. The vacuum cleaner 100 may store a map associated with a space.

The vacuum cleaner 100 may drive to generate a map. In addition, the vacuum cleaner 100 may perform driving according to a moving route determined based on the generated map.

The vacuum cleaner 100 may store a position at which the charging device 200 is disposed. The vacuum cleaner 100 may move to the stored position to perform charging (or to standby). When the vacuum cleaner 100 is moved to the determined position, the charging device 200 may supply power to the vacuum cleaner 100.

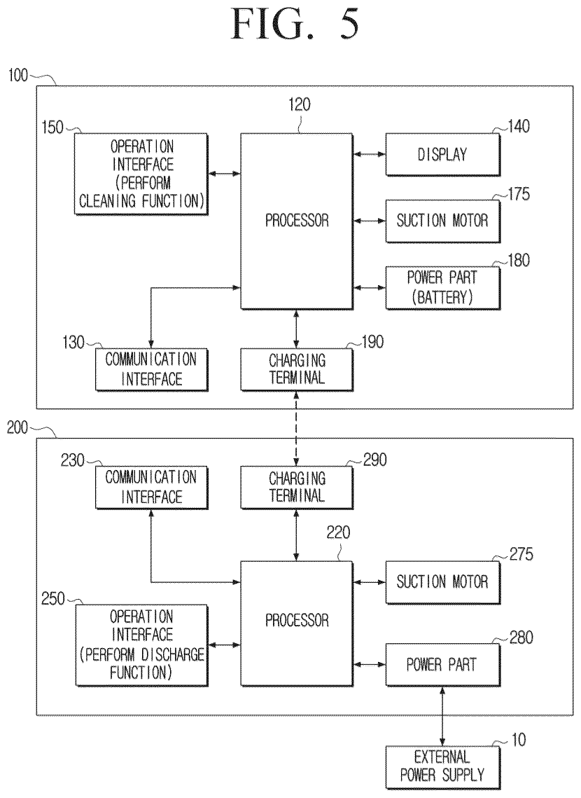

FIG. 5 is a diagram illustrating a structure of the vacuum cleaner 100 and the charging device 200 according to an embodiment.

The vacuum cleaner 100 may include at least one from among the processor 120, the communication interface 130, the display 140, the operation interface 150, the suction motor 175, the power part 180, and the charging terminal 190.

The processor 120 may control the communication interface 130, the display 140, the operation interface 150, the suction motor 175, or the power part 180.

In an example, the processor 120 may control the communication interface 130. The vacuum cleaner 100 may be communicatively connected with the charging device 200 through the communication interface 130.

In an example, the processor 120 may display a given image through the display 140.

In an example, the processor 120 may perform a rotation function by controlling the suction motor 175. If the suction motor 175 is rotated, the vacuum cleaner 100 may perform a suction operation.

In an example, the processor 120 may supply power to the configurations included in the vacuum cleaner 100 through the power part 180.

In an example, the vacuum cleaner 100 may receive a user input through the operation interface 150. The user input may be an input for performing a cleaning function. If the user input is received, the vacuum cleaner 100 may supply power to the suction motor 175 by the power part 180. If the suction motor 175 is rotated, the vacuum cleaner 100 may perform the cleaning function by suctioning surrounding air, dust, and the like.

The vacuum cleaner 100 may be contacted (or connected) with the charging device 200 through the charging terminal 190.

The charging device 200 may include at least one from among a processor 220, a communication interface 230, an operation interface 250, a suction motor 275, a power part 280, and the charging terminal 290.

The charging device 200 may be connected with an external power supply 10. The charging device 200 may receive supply of power from the external power supply 10. The charging device 200 may receive power from the external power supply 10 through the power part 280.

When power is supplied from the external power supply 10, the charging device 200 may transfer the supplied power to the vacuum cleaner 100 through the charging terminal 290. Because the charging terminal 190 of the vacuum cleaner 100 and the charging terminal 290 of the charging device 200 are connected, power of the external power supply 10 may be supplied to the vacuum cleaner 100 through the charging device 200.

When power is supplied to the charging device 200 from the external power supply 10, the charging device 200 may transmit power supplied through the power part 280 to the vacuum cleaner 100 through the charging terminal 290 and the charging terminal 190 of the vacuum cleaner 100. The vacuum cleaner 100 may transmit power supplied through the charging terminal 190 to the power part 180. The power part 180 may charge the battery based on the supplied power.

In an example, the charging device 200 may receive a user input through the operation interface 250. The user input may be an input for performing a function of transferring a foreign material included in the vacuum cleaner 100 to the charging device 200. The charging device 200 may include a debris container (or a foreign material storage pack or a foreign material filter bag or a dust bag) for storing foreign materials. If a user input associated with the debris container is received through the operation interface 250 of the charging device 200, the charging device 200 may perform a function of moving the foreign material stored in the vacuum cleaner 100 to the charging device 200 by opening a cap.

Configurations that perform the same function in the vacuum cleaner 100 and the charging device 200 may be present, respectively. For convenience of distinction, ordinal numbers such as first, second, and the like may be added. In an example, the communication interface 130 of the vacuum cleaner 100 may be described as a first communication interface. The communication interface 230 of the charging device 200 may be described as a second communication interface.

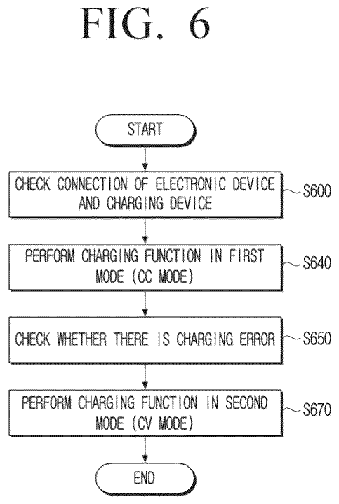

FIG. 6 is a diagram illustrating a charging operation according to an embodiment.

Referring to FIG. 6, the vacuum cleaner 100 may check a connection of the vacuum cleaner 100 and the charging device 200 (S600). The vacuum cleaner 100 may identify whether the charging device 200 is connected. The vacuum cleaner 100 may receive supply of power from the charging device 200. The vacuum cleaner 100 may be connected with the charging device 200 through the charging terminal 190. Descriptions on whether the vacuum cleaner 100 and the charging device 200 have been connected normally will be described in FIG. 7.

If the vacuum cleaner 100 is connected with the charging device 200, the vacuum cleaner 100 may perform the charging function in the first mode. The first mode may be the constant current (CC) mode. The first mode may be a mode for performing the charging function while supplying charging current (or battery current) within the threshold range (or threshold strength).

While performing in the first mode, the vacuum cleaner 100 may check whether the charging error has occurred (S650). The vacuum cleaner 100 may check whether the charging function is normally performed after contacting with the charging device 200. If contact is unstable despite charging power being supplied, charging may not be normally carried out. If the vacuum cleaner 100 and the charging device 200 are not contacted normally, the vacuum cleaner 100 or the charging device 200 may be damaged due to an abnormal supply of charging power.

The vacuum cleaner 100 may check whether the charging function is normally performed. Descriptions associated therewith will be described in FIG. 7 to FIG. 8.

After checking the charging error, the vacuum cleaner 100 may perform the charging function in the second mode (S670). The second mode may be the constant voltage (CV) mode. The second mode may be a mode for performing the charging function while supplying charging voltage within the threshold range (or threshold strength).

The vacuum cleaner 100 may charge the battery using the first mode and the second mode. Descriptions on each of the modes will be described in FIG. 15.

FIG. 7 is a diagram illustrating the charging operation of FIG. 6 in detail according to an embodiment.

Referring to FIG. 7, the vacuum cleaner 100 may check connection with the charging device 200. The vacuum cleaner 100 may identify an occurrence of an initialization event (S710). The initialization event may be a pre-set event generated prior to performing the charging function.

In an example, the initialization event may include at least one from among an event in which power of the vacuum cleaner 100 is turned-on or an event in which the charging terminal 190 of the vacuum cleaner 100 is contacted with the charging terminal 290 of the charging device 200.

The vacuum cleaner 100 may check whether the charging terminal 190 is contacted. If the charging terminal 190 is not contacted with the charging terminal 290 of the charging device 200, the vacuum cleaner 100 may repeat operation S710 repeatedly. If the charging terminal 190 is contacted with the charging terminal 290 of the charging device 200, the vacuum cleaner 100 may perform an initialization function.

When the initialization event occurs (S710-Y), the vacuum cleaner 100 may perform the initialization function (S711). The initialization function may include at least one from among an operation necessary for charging the battery, and an operation for waking-up the communication interface 130 of the vacuum cleaner 100. If the communication interface 130 is not used, the vacuum cleaner 100 may control the communication interface 130 to an off state or a power-saving state. If the initialization event occurs, the vacuum cleaner 100 may change the communication interface 130 from the off state (or power-saving state) to an on state (or activated state).

The vacuum cleaner 100 may identify whether a normal error event has occurred (S720). The normal error event may be described as a first event, a first type event, or the like. The normal error event may be an event set to check charging preparations prior to performing the charging function. If the normal error event occurs, the vacuum cleaner 100 may determine that the charging preparation is not fully prepared.

In an example, the normal error event may include at least one from among an error of the vacuum cleaner 100, an error of the charging device 200, or a disconnection of communication.

In an example, the error of the vacuum cleaner 100 may include at least one from among an error of the power part 180, an error of the suction motor 175, an error of a pressure sensor, an error of the battery 182, and an error of the communication interface 130.

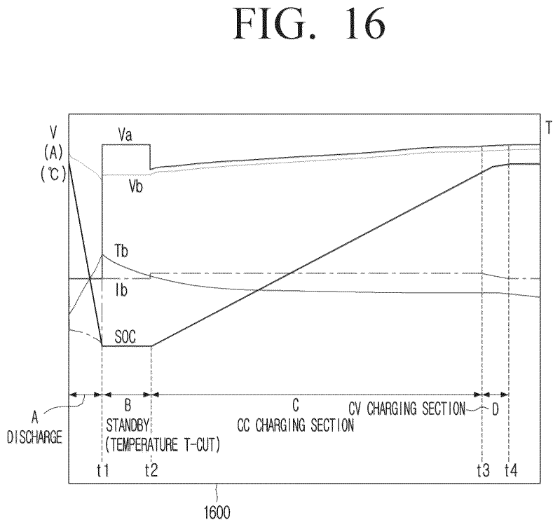

In an example, the error of the power part 180 may include an error indicating that the battery included in the power part 180 is not in a rechargeable state. The error of the power part 180 may include an error indicating that a temperature of the battery 182 is greater than or equal to a threshold temperature. If the temperature of the battery 182 is greater than or equal to the threshold temperature, the vacuum cleaner 100 may not perform the charging function. Descriptions associated therewith will be described in FIG. 16.

In an example, the error of the suction motor 175 may include an error indicating that the suction motor did not rotate normally.

In an example, the error of the pressure sensor may include an error indicating that pressure data of a pre-set size was not identified in the pressure sensor included in the vacuum cleaner 100.

In an example, the error of the charging device 200 may include at least one from among an error of the power part 280, and error of the suction motor 275, an error of a pressure sensor.

In an example, the error of the power part 280 may include an error indicating the battery included in the power part 280 is not in a rechargeable state.

In an example, the error of the suction motor 275 may include an error indicating that the suction motor did not rotate normally.

In an example, the error of the pressure sensor may include an error indicating that pressure data of a pre-set size was not identified in the pressure sensor included in the charging device 200.

If the normal error event did occur, the vacuum cleaner 100 may provide the first error UI (S721). The first error UI may include a UI indicating that the normal error has occurred. The vacuum cleaner 100 may generate a control signal for displaying the first error UI in the vacuum cleaner 100 or the charging device 200. The user may easily recognize that the charging function cannot be performed through the first error UI.

If the normal error event did not occur (S720-N), the vacuum cleaner 100 may operate in the first mode performing the charging function by supplying the battery current (Ib) of threshold strength (S740). In an example, the first mode may be the CC mode.

While operating in the first mode, the vacuum cleaner 100 may check whether the charging error occurred (S750). While performing the charging function in the first mode, the vacuum cleaner 100 may check whether the charging error occurred. Descriptions associated therewith will be described in FIG. 8.

The vacuum cleaner 100 may obtain (or measure) the battery voltage (Vb) while operating in the first mode (S760). The vacuum cleaner 100 may identify whether the battery voltage (Vb) is greater than or equal to the third threshold value (S765). The third threshold value may be changed according to a user setting. If the battery voltage (Vb) is less than the third threshold value (S765-N), the vacuum cleaner 100 may repeat operations S740, S750, S760, and S765.

If the battery voltage (Vb) is greater than or equal to the third threshold value (S765-Y), the vacuum cleaner 100 may operate in the second mode performing the charging function while maintaining the battery voltage (Vb). In an example, the second mode may be the CV mode.

The vacuum cleaner 100 may charge the battery of the vacuum cleaner 100 based on the first mode and the second mode.

FIG. 8 is a diagram illustrating an operation for checking a charging error according to an embodiment.

FIG. 8 may include a description specifying the operation for checking the occurrence of charging error in FIG. 7 (S750). After performing the first mode, the vacuum cleaner 100 may identify (or measure) the battery current (Ib) (S805). The vacuum cleaner 100 may identify whether the battery current (Ib) is greater than or equal to the threshold strength (S810).

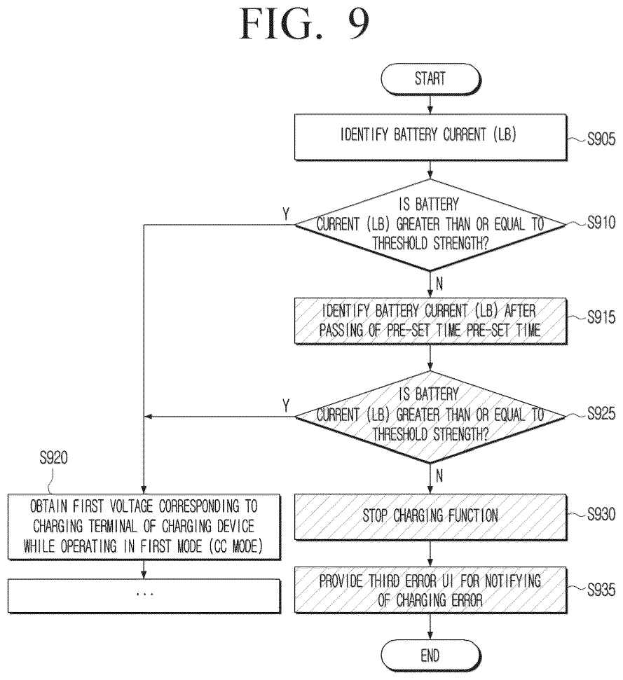

If the battery current (Ib) is less than the threshold strength (S810-N), the vacuum cleaner 100 may repeat operations S805 and S810. In another example, the vacuum cleaner 100 may stop the charging function if the battery current (Ib) is less than the threshold strength. Descriptions associated therewith will be described in FIG. 9.

If the battery current (Ib) is greater than or equal to the threshold strength (S810-Y), the vacuum cleaner 100 may obtain the first voltage (V1) corresponding to the charging terminal 190 of the vacuum cleaner 100 while operating in the first mode (S815). The vacuum cleaner 100 may obtain the second voltage (V2) corresponding to the charging terminal 290 of the charging device 200 while operating in the first mode (S820). The vacuum cleaner 100 may obtain the difference value (Vdiff) of the first voltage (V1) and the second voltage (V2) (S825).

The first voltage (V1) may be voltage measured from the charging terminal 190 of the vacuum cleaner 100, and the second voltage (V2) may be voltage measured from the charging terminal 290 of the charging device 200.

In an example, the difference value may indicate an absolute value. The vacuum cleaner 100 may obtain a value having subtracted the second voltage (V2) from the first voltage (V1). The vacuum cleaner 100 may obtain an absolute value of the subtracted value as the difference value (Vdiff).

The vacuum cleaner 100 may identify whether the difference value (Vdiff) is less than or equal to the first threshold value (S830). The first threshold value may be changed. The smaller the difference value is, the more likely that the vacuum cleaner 100 and the charging device 200 have been contacted normally.

If the difference value (Vdiff) is less than or equal to the first threshold value (S830-Y), the vacuum cleaner 100 may perform the charging function normally (S835). The vacuum cleaner 100 may perform operations S760, S765, and S770 in FIG. 7.

If the difference value (Vdiff) exceeds the first threshold value (S830-N), the vacuum cleaner 100 may identify whether the difference value (Vdiff) is less than or equal to the second threshold value (S840). The second threshold value may be changed.

If the difference value (Vdiff) is less than or equal to the second threshold value (S840-Y), the vacuum cleaner 100 may perform an additional inspection (S845). The vacuum cleaner 100 may perform an operation for additional inspection by re-measuring the first voltage (V1) and the second voltage (V2).

In an example, the vacuum cleaner 100 may repeat operations S805 to S845 for the additional inspection.

In an example, the vacuum cleaner 100 may extend a measuring time for obtaining the first voltage (V1) and the second voltage (V2). Prior to the additional inspection, the vacuum cleaner 100 may obtain the first voltage (V1) and the second voltage (V2) during a first time. At additional inspection, the vacuum cleaner 100 may obtain the first voltage (V1) and the second voltage (V2) during a second time which is longer than the first time.

In an example, the vacuum cleaner 100 may perform a changed inspection operation. The vacuum cleaner 100 may change at least one from among the first threshold value or the second threshold value. The vacuum cleaner 100 may change at least one from among the first threshold value or the second threshold value in order to determine an accurate charging error. The above will be described in FIG. 10.

If the difference value (Vdiff) exceeds the second threshold value (S840-N), the vacuum cleaner 100 may stop (or cease) the charging function (S850). The vacuum cleaner 100 may not supply the charging power to the battery. If the difference value (Vdiff) exceeds the second threshold value, the vacuum cleaner 100 may identify that a problem associated with charging has occurred. Accordingly, the vacuum cleaner 100 may temporarily stop or cease the charging function.

In an example, the vacuum cleaner 100 may stop an operation of the charging voltage of the vacuum cleaner 100 being supplied. The charging voltage of the vacuum cleaner 100 may be the first voltage (V1). The vacuum cleaner 100 may not supply the charging voltage to the battery by turning-off a switch (Sb) for supplying the charging voltage to the battery.

In an example, the vacuum cleaner 100 may stop an operation for the charging voltage of the charging device 200 being supplied. The charging voltage of the charging device 200 may be the second voltage (V2). The vacuum cleaner 100 may generate a control signal for stopping the supply of the charging voltage of the charging device 200. The vacuum cleaner 100 may transmit the generated control signal to the charging device 200 through the communication interface 130. If the control signal is received, the charging device 200 may not supply the charging voltage of the charging device 200 to the vacuum cleaner 100 any further. The charging device 200 may not supply the charging power (or charging voltage) to the vacuum cleaner 100 through the switch included in the charging device 200.

The vacuum cleaner 100 may provide the second error UI for notifying of the charging error (S855). If the second error UI is provided, the user may easily recognize that a problem associated with charging has occurred.

In an example, the vacuum cleaner 100 may display the second error UI through the display 140 included in the vacuum cleaner 100.

In an example, the vacuum cleaner 100 may display the second error UI through an optical device (e.g., LED, LCD) included in the vacuum cleaner 100.

In an example, the vacuum cleaner 100 may display the second error UI through a display 240 included in the charging device 200. The vacuum cleaner 100 may generate a control signal for displaying the second error UI in the display 240, and transmit the generated control signal to the charging device 200 through the communication interface 130.

In an example, the vacuum cleaner 100 may display the second error UI through an optical device (e.g., LED) included in the charging device 200. The vacuum cleaner 100 may generate a control signal for displaying the second error UI in the optical device (e.g., LED), and transmit the generated control signal to the charging device 200 through the communication interface 130.

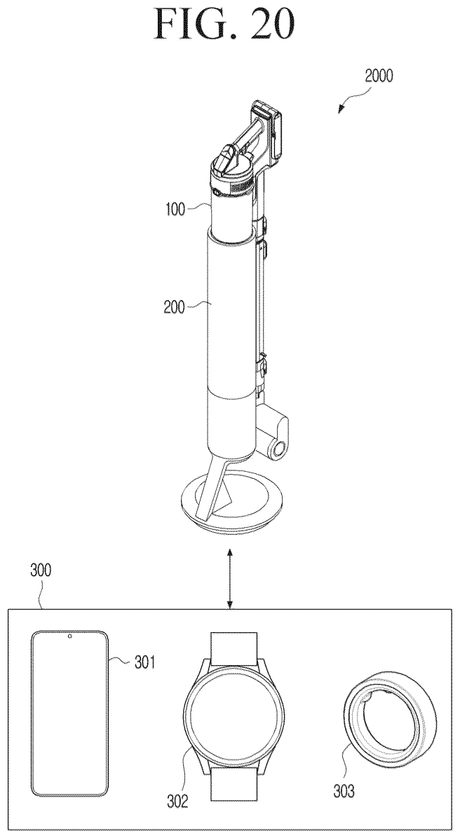

In an example, the vacuum cleaner 100 may generate a control signal for displaying the second error UI in a terminal device 300 which is connectable with the vacuum cleaner 100. The vacuum cleaner 100 may transmit the control signal to the terminal device 300. Descriptions associated therewith will be described in FIG. 20.

FIG. 9 is a diagram illustrating an operation for checking battery current according to an embodiment.

Operations S905, S910, and S920 in FIG. 9 may correspond to operations S805, S810, and S820 in FIG. 8. Redundant descriptions thereof will be omitted.

If the battery current (Ib) is greater than or equal to the threshold strength (S910-Y), the vacuum cleaner 100 may perform operation S920. After operation S920, operations S825 to S855 in FIG. 8 may be performed.

If the battery current (Ib) is less than the threshold strength (S910-N), the vacuum cleaner 100 may identify battery current (Ib) after a pre-set time has passed (S915). The vacuum cleaner 100 may re-identify whether the battery current (Ib) is greater than or equal to the threshold strength (S925).

If the re-identified battery current (Ib) is greater than or equal to the threshold strength (S925-Y), the vacuum cleaner 100 may perform operation S920 and operations thereafter (S825 to S855 in FIG. 8).

If the re-identified battery current (Ib) is less than the threshold strength (S925-N), the vacuum cleaner 100 may stop the charging function (S930). The vacuum cleaner 100 may control for the charging power to not be supplied to the battery of the vacuum cleaner 100. An operation for stopping the charging function may correspond to operation S850 in FIG. 8.

The vacuum cleaner 100 may provide a third error UI for notifying of the charging error (S935). The third error UI may include information indicating that the first mode was not normally operated.

FIG. 10 is a diagram illustrating an operation for checking voltage difference according to an embodiment.

Referring to FIG. 10, the vacuum cleaner 100 may identify whether an additional inspection event has occurred (S1005). The additional inspection event may include an event for performing operation S845 in FIG. 8. The additional inspection event may indicate an event included in a range where it is difficult to determine whether the difference value (Vdiff) is normal or an error.

If the additional inspection event occurs (S1005-Y), the vacuum cleaner 100 may change the first threshold value to a fourth threshold value (S1010). The vacuum cleaner 100 may change the second threshold value to a fifth threshold value (S1011).

In an example, the fourth threshold value may be higher than the first threshold value. In an example, the fifth threshold value may be lower than the second threshold value. The vacuum cleaner 100 may change at least a portion from among the threshold values for a more accurate analysis.

In an example, the fourth threshold value may be smaller than the fifth threshold value.

The vacuum cleaner 100 may obtain the first voltage (V1) corresponding to the charging terminal 190 of the vacuum cleaner 100 while operating in the first mode (S1015). The vacuum cleaner 100 may obtain the second voltage (V2) corresponding to the charging terminal 290 of the charging device 200 while operating in the first mode (S1020). The vacuum cleaner 100 may obtain the difference value (Vdiff) of the first voltage (V1) and the second voltage (V2) (S1025).

In an example, the difference value may indicate the absolute value. The vacuum cleaner 100 may obtain a value of having subtracted the second voltage (V2) from the first voltage (V1). The vacuum cleaner 100 may obtain the absolute value of the subtracted value as the difference value (Vdiff).

The vacuum cleaner 100 may identify whether the difference value (Vdiff) is less than or equal to the fourth threshold value (S1030). The smaller the difference value is, it may indicate that the vacuum cleaner 100 and the charging device 200 have been contacted normally.

If the difference value (Vdiff) is less than or equal to the fourth threshold value (S1030-Y), the vacuum cleaner 100 may perform the charging function normally (S1035). The vacuum cleaner 100 may perform operations S760, S765, and S770 in FIG. 7.

If the difference value (Vdiff) exceeds the fourth threshold value (S1030-N), the vacuum cleaner 100 may identify whether the difference value (Vdiff) is less than or equal to the fifth threshold value S1040). The fifth threshold value may be changed.

If the difference value (Vdiff) is less than or equal to the fifth threshold value (S1040-Y), the vacuum cleaner 100 may perform an additional inspection (S1045). The vacuum cleaner 100 may perform an additional inspection operation by re-measuring the first voltage (V1) and the second voltage (V2).

If the difference value (Vdiff) exceeds the fifth threshold value (S1040-N), the vacuum cleaner 100 may stop (or cease) the charging function (S1050). The vacuum cleaner 100 may not supply charging power to the battery. If the difference value (Vdiff) exceeds the fifth threshold value, the vacuum cleaner 100 may identify that a problem associated with charging has occurred. Accordingly, the vacuum cleaner 100 may temporarily stop or cease the charging function.

The vacuum cleaner 100 may provide the second error UI for notifying of the charging error (S1055). If the second error UI is provided, the user may easily recognize that the problem associated with charging has occurred.

Operations S1015 to S1055 in FIG. 10 may correspond to operations S815 to S855 in FIG. 8 except for the threshold value. Redundant descriptions thereof will be omitted.

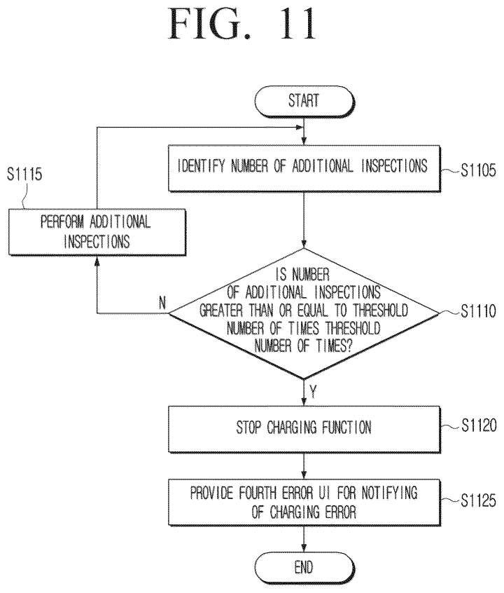

FIG. 11 is a diagram illustrating an operation for calculating a number of additional inspections according to an embodiment.

Referring to FIG. 11, the vacuum cleaner 100 may identify a number of additional inspections (S1105). The additional inspections may indicate the inspections performed by operation S845 in FIG. 8 and operation S1045 in FIG. 10.

The vacuum cleaner 100 may identify whether the number of additional inspections is greater than or equal to a threshold number of times (S1110). If the number of additional inspections is less than the threshold number of times (S1010-N), the vacuum cleaner 100 may perform an additional inspection (S1115).

If the number of additional inspections is greater than or equal to the threshold number of times (S1010-Y), the vacuum cleaner 100 may stop the charging function. The vacuum cleaner 100 may control for the charging power to not be supplied to the battery of the vacuum cleaner 100. An operation for stopping the charging function may correspond to operation S850 in FIG. 8.

The vacuum cleaner 100 may provide a fourth error UI for notifying of the charging error (S1025). The fourth error UI may be a UI provided when the difference value (Vdiff) falls within an error range. The fourth error UI may include information for notifying that there is a possibility of the charging function not being performed normally despite not knowing an exact cause.

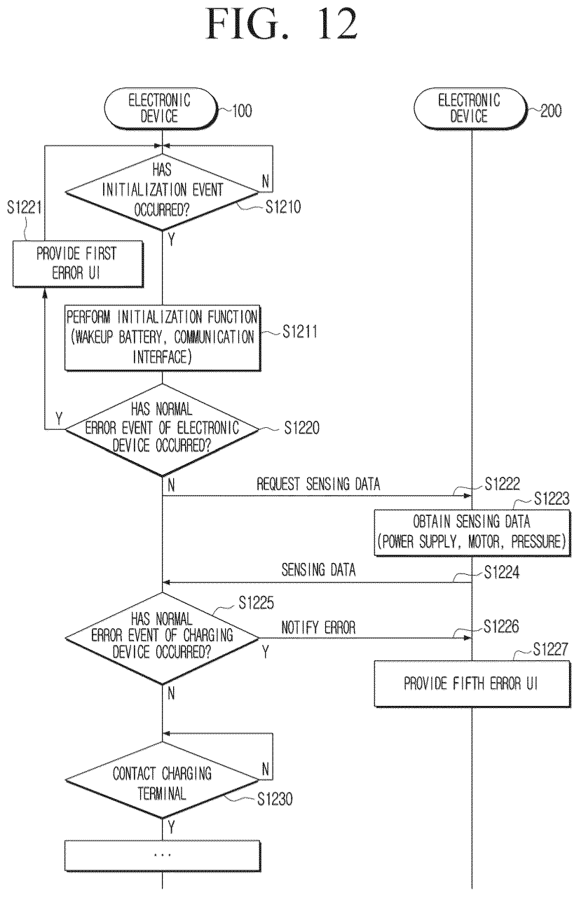

FIG. 12 is a diagram illustrating an operation for requesting sensing data to the charging device 200 according to an embodiment.

Steps S1210, S1211, S1221, and S1230 in FIG. 12 may correspond to steps S710, S711, S721, and S730 in FIG. 7. Redundant descriptions thereof will be omitted.

The normal error event described in step S720 in FIG. 7 may include at least one from among a normal error event of the vacuum cleaner 100 or a normal error event of the charging device 200.

After performing the initialization function, the vacuum cleaner 100 may identify whether the normal error event of the vacuum cleaner 100 has occurred (S1220).

The normal error event of the vacuum cleaner 100 may include at least one from among the error of the power part 180, the error of the suction motor 175, and the error of the pressure sensor. Descriptions associated therewith will be described in operation S720 in FIG. 7.

If the normal error event of the vacuum cleaner 100 occurs (S1220-Y), the vacuum cleaner 100 may provide the first error UI (S1221). The first error UI may include information indicating that an error has occurred in the vacuum cleaner 100.

If the normal error event of the vacuum cleaner 100 does not occur (S1220-N), the vacuum cleaner 100 may request sensing data to the charging device 200 (S1222).

The charging device 200 may receive the request for sensing data from the vacuum cleaner 100. The charging device 200 may obtain the sensing data (S1223). The sensing data may include at least one from among data associated with the power part 280, data associated with the suction motor 275, and data associated with the pressure sensor. The charging device 200 may transmit the sensing data to the vacuum cleaner 100 (S1224).

The vacuum cleaner 100 may receive the sensing data from the charging device 200. The vacuum cleaner 100 may identify whether the normal error event of the charging device 200 has occurred based on sensing data of the charging device 200 (S1225).

The normal error event of the charging device 200 may include at least one from among the error of the power part 280, the error of the suction motor 275, and the error of the pressure sensor. Descriptions associated therewith will be described in operation S720 in FIG. 7. The vacuum cleaner 100 may determine whether the normal error event of the charging device 200 has occurred based on the sensing data.

If the normal error event of the charging device 200 occurs (S1225-Y), the vacuum cleaner 100 may transmit an error notification to the charging device 200 (S1226). The vacuum cleaner 100 may generate a control signal for providing a fifth error UI in the charging device 200. The vacuum cleaner 100 may transmit the generated control signal to the charging device 200. The control signal may include the error notification.

The charging device 200 may receive the error notification from the vacuum cleaner 100. The charging device 200 may provide the fifth error UI based on the error notification (S1227). The fifth error UI may include information indicating that an error associated with the charging device 200 has occurred.

If the normal error event of the charging device 200 has not occurred (S1225-N), the vacuum cleaner 100 may check whether the charging terminal 190 is contacted (S1230). The vacuum cleaner 100 may perform operations S740 to S770 in FIG. 7 after operation S1230.

FIG. 13 is a diagram illustrating an operation for calculating voltage difference according to an embodiment.

Referring to FIG. 13, the charging terminal 190 of the vacuum cleaner 100 may include the first terminal 191 and the second terminal 192. The first terminal 191 may be a negative electrode terminal or a ground terminal of the charging terminal 190. The second terminal 192 may be a positive electrode terminal of the charging terminal 190 or a terminal that is supplied with charging voltage.

The first terminal 191 may be connected to a first end (a) of first resistance (R1).

A second end (b) of the first resistance (R1) may be connected to a microcontroller 121 of the vacuum cleaner 100, and a first end (a) of second resistance (R2). A processor for measuring voltage of the microcontroller 121 may be included. The microcontroller 121 may be described as a voltage measuring module.

The second terminal 192 may be connected to a second end (b) of the second resistance (R2) and the power part 180.

The vacuum cleaner 100 may obtain voltage for a node connected with the second terminal 192 as the first voltage (V1).

The vacuum cleaner 100 may obtain the voltage for the node connected with the second end (b) of the first resistance (R1) and the first end (a) of the second resistance (R2) as third voltage (V3).

Referring to Equation 1310, the third voltage (V3) may be calculated based on the first voltage (V1), the first resistance (R1), and the second resistance (R2).

Referring to Equation 1320, the first voltage (V1) may be calculated based on the third voltage (V3), the first resistance (R1), and the second resistance (R2).

The vacuum cleaner 100 may obtain the third voltage (V3) through the microcontroller 121. According to Equation 1320, the vacuum cleaner 100 may obtain the first voltage (V1) based on the third voltage (V3), the first resistance (R1), and the second resistance (R2). The first voltage (V1) may be obtained based on the third voltage (V3), the first resistance (R1), and the second resistance (R2).

The charging terminal 290 of the charging device 200 may include the first terminal 291 and the second terminal 292. The first terminal 291 may be the negative electrode terminal or the ground terminal of the charging terminal 290. The second terminal 292 may be the positive electrode terminal of the charging terminal 290 or a terminal that supplies the charging voltage.

The first terminal 291 may be connected to a first end (a) of third resistance (R3).

The second end (b) of the third resistance (R3) may be connected to a microcontroller 221 of the charging device 200 and a first end (a) of fourth resistance (R4). The microcontroller 221 may include a processor for measuring voltage. The microcontroller 221 may be described as a voltage measuring module.

The second terminal 292 may be connected with a second end (b) of the fourth resistance (R4) and the power part 280.

The charging device 200 may obtain voltage for a node connected with the second terminal 292 as the second voltage (V2).

The charging device 200 may obtain voltage for a node connected with the second end (b) of the third resistance (R3) and a first end (a) of the fourth resistance (R4) as a fourth voltage (V4).

Referring to Equation 1330, the fourth voltage (V4) may be calculated based on the second voltage (V2), the third resistance (R3), and the fourth resistance (R4).

Referring to Equation 1340, the second voltage (V2) may be calculated based on the fourth voltage (V4), the third resistance (R3), and the fourth resistance (R4).

The vacuum cleaner 100 may obtain the fourth voltage (V4) through the microcontroller 221. According to Equation 1340, the vacuum cleaner 100 may obtain the second voltage (V2) based on the fourth voltage (V4), the third resistance (R3), and the fourth resistance (R4). The second voltage (V2) may be obtained based on the fourth voltage (V4), the third resistance (R3), and the fourth resistance (R4).

In an example, the charging device 200 may transfer power supplied from the external power supply 10 to the charging terminal 290 through the power part 280. If the charging terminal 190 of the vacuum cleaner 100 is contacted with the charging terminal 290 of the charging device 200, the charging device 200 may transfer power to the vacuum cleaner 100. The vacuum cleaner 100 may transfer power transferred from the charging device 200 to the power part 180.

In an example, the vacuum cleaner 100 may first obtain the third voltage through the microcontroller 121, and obtain the first voltage based on Equation 1320.

In an example, the charging device 200 may first obtain the fourth voltage through the microcontroller 221, and obtain the second voltage based on Equation 1340.

According to Equation 1350, the vacuum cleaner 100 may obtain the difference value (Vdiff) of the first voltage (V1) and the second voltage (V2).

The vacuum cleaner 100 may obtain the absolute value of the subtracted value of the first voltage (V1) and the second voltage (V2) as the difference value (Vdiff). According to Equation 1350, the vacuum cleaner 100 may obtain the difference value (Vdiff) based on the third voltage (V3), the fourth voltage (V4), the first resistance (R1), the second resistance (R2), the third resistance (R3), and the fourth resistance (R4).

FIG. 14 is a diagram illustrating battery current, battery voltage, and equivalent resistance according to an embodiment.

Referring to FIG. 14, the power part 180 of the vacuum cleaner 100 may include at least one from among a variable power part 181, the battery 182, the switch (Sb) 183, and an external resistance (Ra) 184.

The variable power part 181 may supply power according to control of the vacuum cleaner 100.

The battery 182 may include at least one from among an internal resistance (Rb) 182-1 or an internal power supply (Vb) 182-2.

The external resistance (Ra) may be disposed so as to be connected to the variable power part 181 and the battery 182. In an example, the external resistance (Ra) may be a variable resistance. A resistance value of the external resistance (Ra) may be changed according to control of the vacuum cleaner 100.

The internal resistance (Rb) may be included in the battery 182.

The internal resistance (Rb) may be described as an internal impedance. The internal resistance (Rb) may be a variable resistance.

The external resistance (Ra) may be described as a fifth resistance. The internal resistance (Rb) may be described as a sixth resistance.

Voltage between a first end (a) and a second end (b) of the variable power part 181 may be a charging voltage (Va). According to Equation 1410, the vacuum cleaner 100 may obtain the charging voltage (Va) based on the first voltage (V1) and a constant (k). The constant (k) may be changed.

Current flowing from the variable power part 181 to the battery 182 may be the battery current (Ib). According to Equation 1420, the vacuum cleaner 100 may obtain the battery current (Ib) based on the charging voltage (Va), the battery voltage (Vb), and the external resistance (Ra). The external resistance (Ra) may be described as an external resistance value.

Voltage between a first end (a) and a second end (b) of the battery 182 may be the battery voltage (Vb).

A resistance value of the internal resistance 182-1 may be changed according to control of the vacuum cleaner 100. The internal resistance 182-1 may be described as an equivalent resistance or an equivalent impedance.

The vacuum cleaner 100 may determine whether to supply the charging voltage (Va) to the battery 182 by controlling the switch 183. If the switch 183 is in the on state, the charging voltage (Va) may be supplied to the battery 182. To stop the charging function, the vacuum cleaner 100 may control the switch 183 to the on state (or close state).

If the switch 183 is in the off state, the charging voltage (Va) may not be supplied to the battery 182. To perform the charging function, the vacuum cleaner 100 may control the switch 183 to the off state (or open state).

The first end (a) of the variable power part 181 may be connected to the first end (a) of the battery 182.

The first end (a) of the battery 182 may be connected to a first end (a) of the internal resistance 182-1 and a first end (a) of the internal power supply 182-2.

A second end (b) of the internal resistance 182-1 may be connected to a second end (b) of the internal power supply 182-2 and the second end (b) of the battery 182.

The second end (b) of the battery 182 may be connected to a second end (b) of the switch 183.

A first end (a) of the switch 183 may be connected to a second end (b) of the external resistance 184.

A first end (a) of the external resistance 184 may be connected to the second end (b) of the variable power part 181.

FIG. 15 is a diagram illustrating battery current, battery voltage, and equivalent resistance according to an embodiment.

Referring to graph 1500 in FIG. 15, the vacuum cleaner 100 may perform a charging function. The vacuum cleaner 100 may perform the charging function while performing in the first mode (CC mode) or the second mode (CV mode).

The vacuum cleaner 100 may perform in the first mode (CC mode) maintaining the battery current (Ib) constant (at a constant range) in order to perform the charging function. Because charging is performed while the first mode (CC mode) is performed, battery voltage (Vb) may progressively increase.

The vacuum cleaner 100 may identify whether the battery voltage (Vb) is greater than or equal to the third threshold value (th3). If an event of the battery voltage (Vb) increasing from less than the third threshold value to the third threshold value is identified, the vacuum cleaner 100 may change the first mode (CC mode) to the second mode (CV mode). The second mode (CV mode) may be a mode for maintaining the battery voltage (Vb) constant (at a constant range).

In an example, battery voltage (Vb) in the second mode may rise to less than or equal to a threshold speed. Battery voltage (Vb) in the first mode may rise to a first speed. The battery voltage (Vb) in the second mode may rise to a second speed which is lower than the first speed.

At a time point (t3) at which an event increasing the battery voltage (Vb) from less than the third threshold value to the third threshold value occurs, the vacuum cleaner 100 may change the first mode (CC mode) to the second mode (CV mode).

An operation for maintaining battery current (Ib) or the battery voltage (Vb) constant (at the constant range) may include an operation for controlling the variable power part 181 for battery current (Ib) or battery voltage (Vb) to be supplied within the threshold range.

In an example, the vacuum cleaner 100 may change the resistance value of the internal resistance 182-1 while maintaining the battery current (Ib) at the constant range in the first mode (CC mode).

In an example, while performing in the first mode (CC mode), the resistance value of the internal resistance 182-1 may be changed.

In an example, the vacuum cleaner 100 may change the resistance value of the internal resistance 182-1 while the battery voltage (Vb) is maintained at the constant range in the second mode (CV mode).

The constant range of the battery voltage (Vb) and the constant range of the battery current (Ib) may be different.

In an example, while performing in the second mode (CV mode), the resistance value of the internal resistance 182-1 may be changed.

FIG. 16 is a diagram illustrating battery temperature, and charge amount according to an embodiment.

Referring to graph 1600 in FIG. 16, the vacuum cleaner 100 may perform an electric operation using the battery 182 prior to a first time point (t1). The battery 182 may be discharged. While the battery 182 is being discharged, battery voltage (Vb) of the battery 182 may be reduced, temperature (Tb) of the battery 182 may be reduced, and a charge capacity (state or charge (SOC)) of the battery 182 may be reduced.

The vacuum cleaner 100 may assume that a control signal for performing the charging function is generated at the first time point (t1). The first voltage (V1) may rise at the first time point (t1). If power is supplied from the charging device 200, the first voltage (V1) may be raised. However, the battery voltage (Vb) of the vacuum cleaner 100 may be immediately rise. The vacuum cleaner 100 may check the temperature of the battery 182 prior to performing the charging function.

If the temperature of the battery 182 is greater than or equal to a threshold temperature, the vacuum cleaner 100 may not perform the charging function.

In an example, if the temperature of the battery 182 is greater than or equal to the threshold temperature, the vacuum cleaner 100 may not supply the first voltage (V1) to the battery 182 by controlling the switch 183 to the off state.

In an example, if the temperature of the battery 182 is greater than or equal to the threshold temperature, the vacuum cleaner 100 may lower the charging voltage (Va) by controlling the constant (k) of Equation 1410 in FIG. 14.

It may be assumed that a temperature (Tb) of the battery 182 is less than or equal to the threshold temperature at a second time point (t2). The vacuum cleaner 100 may perform the charging function in the first mode (CC mode) at the second time point (t2). While performing in the first mode (CC mode), the battery voltage (Vb) of the battery 182 may be raised, and the charge capacity (SOC) of the battery 182 may be raised.

It may be assumed that the battery voltage (Vb) has become greater than or equal to the third threshold value at a third time point (t3). The vacuum cleaner 100 may perform the charging function in the second mode (CV mode) from the third time point (t3). While performing in the second mode (CV mode), the battery voltage (Vb) of the battery 182 may be raised, and a charging capacity (SOC) of the battery 182 may be raised. The charging capacity (SOC) of the battery 182 may all be charged at a fourth time point (t4).

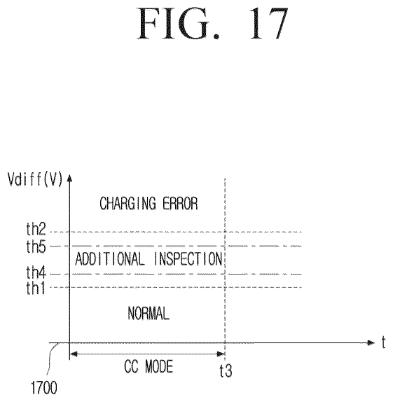

FIG. 17 is a diagram illustrating an operation for analyzing voltage difference according to an embodiment.

Referring to graph 1700 in FIG. 17, the vacuum cleaner 100 may check the charging error based on the difference value (Vdiff). The vacuum cleaner 100 may identify whether the charging error has occurred by analyzing the difference value (Vdiff).

If the difference value (Vdiff) is less than a first threshold value (th1), the vacuum cleaner 100 may determine that the charging error has not occurred. The vacuum cleaner 100 may perform the charging function normally. The vacuum cleaner 100 may perform the charging function in the first mode (CC mode).

If the difference value (Vdiff) exceeds the first threshold value (th1) and is less than or equal to a second threshold value (th2), the vacuum cleaner 100 may perform an additional inspection.

If the difference value (Vdiff) exceeds the second threshold value (th2), the vacuum cleaner 100 may identify as the charging error having occurred.

The vacuum cleaner 100 may obtain the difference value (Vdiff) while performing in the first mode (CC mode). A reason for obtaining the difference value (Vdiff) in the first mode (CC mode) is because the difference value (Vdiff) is clearly distinguished.

Through an operation for changing the threshold value described in FIG. 10, the vacuum cleaner 100 may obtain a fourth threshold value (th4) and a fifth threshold value (th5).

The fourth threshold value (th4) may be greater than the first threshold value (th1) and smaller than the fifth threshold value (th5).

The fifth threshold value (th5) may be greater than the fourth threshold value (th4) and smaller than the second threshold value (th2).

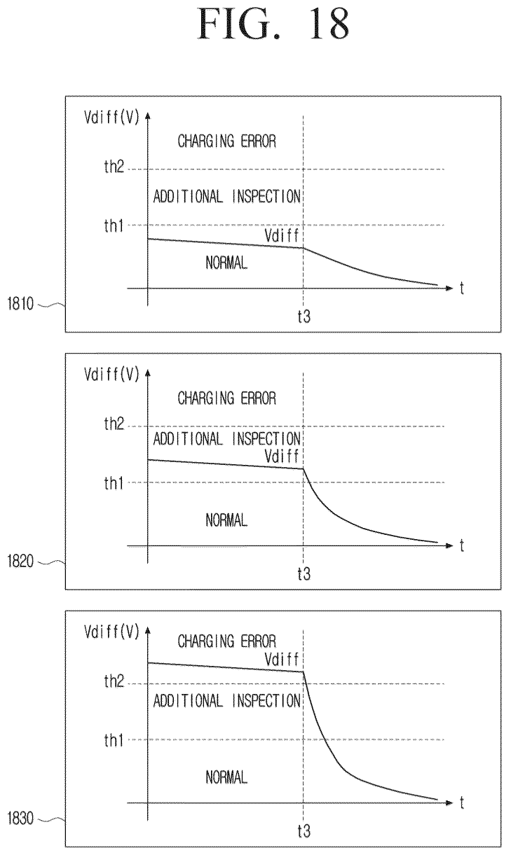

FIG. 18 is a diagram illustrating analysis results corresponding to voltage differences according to an embodiment.

Referring to embodiment 1810 in FIG. 18, the difference value (Vdiff) obtained in the first mode (CC mode) may be less than or equal to the first threshold value (th1). The vacuum cleaner 100 may determine that the charging error will not occur. The vacuum cleaner 100 may perform the charging function normally.

Referring to embodiment 1820 in FIG. 18, the difference value (Vdiff) obtained in the first mode (CC mode) may exceed the first threshold value (th1) and may be less than or equal to the second threshold value (th2). The vacuum cleaner 100 may determine as performing an additional inspection.

Referring to embodiment 1830 in FIG. 18, the difference value (Vdiff) obtained in the first mode (CC mode) may exceed the second threshold value (th2). The vacuum cleaner 100 may determine as the charging error having occurred. The vacuum cleaner 100 may case the charging function.

A reason for analyzing the difference value (Vdiff) in the first mode (CC mode) is because the difference value (Vdiff) obtained in the first mode (CC mode) can clearly indicate an error occurrence according to circumstance. It may be assumed that the first mode (CC mode) is changed to the second mode (CV mode) at the third time point (t3). After the third time point (t3), the difference value (Vdiff) may be drastically reduced. Accordingly, it may be more difficult to accurately identify the occurrence of charging error from the difference value (Vdiff) obtained in the second mode (CV mode) than in the first mode (CC mode).

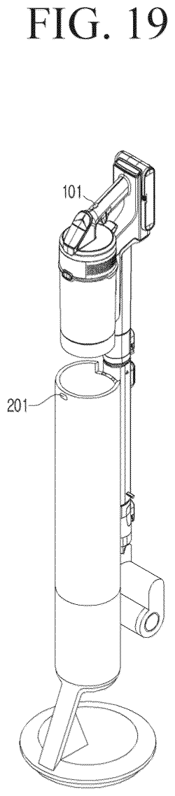

FIG. 19 is a diagram illustrating an operation for when an error occurs according to an embodiment.

Referring to FIG. 19, the vacuum cleaner 100 may include an optical device 101. The charging device 200 may include an optical device 201.

In an example, the optical devices 101 and 201 may include LEDs.

The vacuum cleaner 100 may provide an error UI through the optical device 101. If an error is identified as having occurred, the vacuum cleaner 100 may control the optical device 101 to output a pre-set color (e.g., red).

The charging device 200 may provide an error UI through the optical device 201. If an error is identified as having occurred, the charging device 200 may control the optical device 201 to output a pre-set color (e.g., red).

The error UI may include at least one from among the first error UI of operation S721 in FIG. 7, the second error UI of operation S855 in FIG. 8, the third error UI of operation S935 in FIG. 9, the second error UI of operation S1055 in FIG. 10, the fourth error UI of operation S1125 in FIG. 11, the first error UI of operation S1221 in FIG. 12, and the fifth error UI of operation S1227 in FIG. 12.

In an example, the vacuum cleaner 100 may provide an error UI by outputting the pre-set color differently according to a type of the error. The vacuum cleaner 100 may distinguish whether the error is the normal error (S720 in FIG. 7) or the charging error (S750 in FIG. 7). If the normal error occurs, the vacuum cleaner 100 may output an error UI in a first color through the optical device 101 or the optical device 201. If the charging error occurs, the vacuum cleaner 100 may output an error UI in a second color different from the first color through the optical device 101 or the optical device 201

In an example, the vacuum cleaner 100 may identify a target device corresponding to an error. The vacuum cleaner 100 may provide an error UI with only an optical device included in the target device. The vacuum cleaner 100 may identify the target device corresponding to a cause for the error having occurred. The vacuum cleaner 100 may provide an error UI of a pre-set color through the optical device included in the target device. If the cause of the error is the vacuum cleaner 100, the vacuum cleaner 100 may provide the error UI using only the optical device 101. If the cause of the error is the charging device 200, the vacuum cleaner 100 may provide the error UI using only the optical device 201.

FIG. 20 is a diagram illustrating an error UI being provided to terminal devices 300 according to an embodiment.

Referring to embodiment 2000 in FIG. 20, the vacuum cleaner 100 or the charging device 200 may be communicatively connected with the terminal device 300. The vacuum cleaner 100 or the charging device 200 may provide the error UI through the terminal device 300. The vacuum cleaner 100 or the charging device 200 may transmit information associated with the error UI to the terminal device 300. The terminal device 300 may provide an error UI based on information associated with the error UI received from the vacuum cleaner 100 or the charging device 200.

In an example, the vacuum cleaner 100 may be connected with the terminal device 300 through an access point (AP) device. The AP device may be a device which manages and connects an Internet of Things (IoT) network.

In an example, the vacuum cleaner 100 may be directly connected with the terminal device 300 based on a pre-set communication method (Wi-Fi or Bluetooth).

In an example, the terminal device 300 may include at least one from among a smart phone 301, a smart watch 302, or a smart ring 303.

FIG. 21 is a diagram illustrating a first error UI according to an embodiment.

Referring to FIG. 21, the vacuum cleaner 100 may provide a screen 2100 for notifying of the normal error. The screen 2100 may include at least one from among a UI 2110 indicating that preparations for charging is not prepared, a UI 2120 for guiding charging preparations and an image 2130 for guiding the charging preparations.

In an example, it may be assumed that a power cord of the charging device 200 is not connected to an external power supply. If power supply is not carried out from the charging device 200, the vacuum cleaner 100 may identify that the normal error event has occurred. If the normal error event has occurred, the vacuum cleaner 100 may provide the first error UI. The screen 2100 may be a screen that includes the first error UI. The first error UI may include information indicating that the charging device 200 is not normally connected to the external power supply.

The vacuum cleaner 100 may provide the first error UI through at least one from among the vacuum cleaner 100, the charging device 200, or the terminal device 300.

FIG. 22 is a diagram illustrating a second error UI according to an embodiment.

Referring to FIG. 22, the vacuum cleaner 100 may provide a screen 2200 for notifying of the charging error. The screen 2200 may include at least one from among a UI 2210 indicating that an error associated with the charging function has occurred, a UI 2220 for guiding a charging method, and an image 2130 for guiding the charging method.

In an example, it may be assumed that a gap between the charging terminals 190 and 290 is misaligned due to the vacuum cleaner 100 and the charging device 200 not being normally coupled. It may be assumed that the charging function has been performed despite the vacuum cleaner 100 and the charging device 200 not being normally coupled. If the charging function has been performed, the difference value (Vdiff) may exceed the second threshold value (th2). The vacuum cleaner 100 may identify the charging error. If the charging error is identified, the vacuum cleaner 100 may identify the cause for the charging error having occurred, and provide the second error UI including guide information for solving the problem. The screen 2200 may be a screen that includes the second error UI. The second error UI may include information indicating that the charging terminal 190 of the vacuum cleaner 100 is not normally connected.

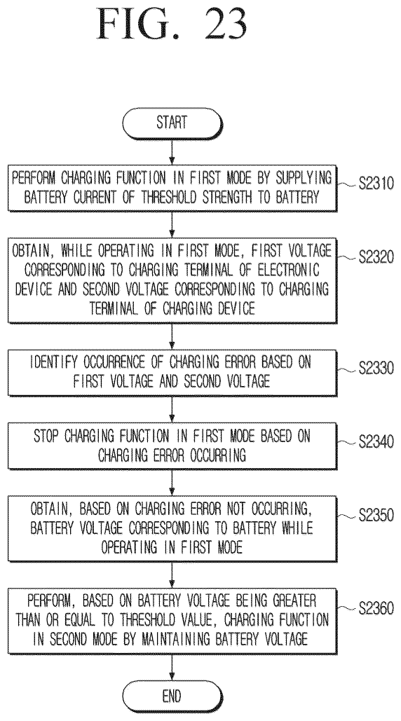

FIG. 23 is a diagram illustrating a control method of an electronic device according to an embodiment.

Referring to FIG. 23, a control method of an electronic device which includes a rechargeable battery and a charging terminal that connects with a charging device may include performing in a first mode a charging function by supplying battery current of threshold strength to a battery (S2310), obtaining, while operating in the first mode, first voltage corresponding to the charging terminal of the electronic device and second voltage corresponding to a charging terminal of the charging device (S2320), identifying an occurrence of charging error based on the first voltage and the second voltage (S2330), ceasing, based on the charging error occurring, the charging function in the first mode (S2340), obtaining, based on the charging error not occurring, battery voltage corresponding to the battery while operating in the first mode (S2350), and performing, based on the battery voltage being greater than or equal to a threshold value, the charging function in a second mode by maintaining the battery voltage (S2360).

The charging error may include an error of a coupling position of the charging terminal of the electronic device and the charging terminal of the charging device not matching.

The identifying an occurrence of charging error (S2330) may include obtaining a charging device of the first voltage and the second voltage, and identifying the occurrence of charging error based on the difference value.

The identifying an occurrence of charging error (S2330) may include continuing to operate in the first mode based on the difference value being less than or equal to a first threshold value, and identifying that the charging error has occurred based on the difference value exceeding a second threshold value that is greater than the first threshold value, and the threshold value may be a third threshold value.

The identifying an occurrence of charging error (S2330) may include identifying, based on the difference value exceeding the first threshold value and being less than or equal to the second threshold value, the occurrence of charging error by re-obtaining the first voltage and the second voltage.

The ceasing the charging function in the first mode may include ceasing, based on the charging error occurring, the charging function in the first mode by controlling a switch included in the electronic device to an off state.

The control method may include providing, based on the charging error occurring, an error UI indicating the charging error.

The control method may include activating a communication interface included in the electronic device based on the charging terminal of the electronic device and the charging terminal of the charging device being contacted, requesting, through the communication interface, a response from the charging device, identifying that a normal error has occurred based on a response signal not being received from the charging device through the communication interface, and providing an error UI indicating that the normal error has occurred.

The control method may include performing the charging function in the first mode based on the response signal being received from the charging device through the communication interface.

The first mode may be a constant current (CC) mode which maintains a strength of the battery current to the threshold strength, and the second mode may be a constant voltage (CV) mode which maintains the battery voltage within the threshold range.

Meanwhile, the methods according to the various embodiments of the disclosure described above may be implemented in an application form installable in electronic devices of the related art.

The methods according to the various embodiments of the disclosure described above may be implemented with only a software upgrade, or a hardware upgrade for the electronic device of the related art.

The various embodiments of the disclosure described above may be performed through an embedded server provided in the electronic device, or at least one external server from among the electronic device and the display device.

According to an embodiment of the disclosure, the various embodiments described above may be implemented with software including instructions stored in a machine-readable storage media (e.g., a computer). The machine may call a stored instruction from a storage medium, and as a device operable according to the called instruction, may include the electronic device according to the above-mentioned embodiments. Based on a command being executed by the processor, the processor may directly or using other elements under the control of the processor perform a function relevant to the command. The command may include a code generated by a compiler or executed by an interpreter. The machine-readable storage media may be provided in a form of a non-transitory storage medium. Herein, ‘non-transitory’ merely means that a storage medium is tangible and does not include a signal, and the term does not differentiate data being semi-permanently stored or being temporarily stored in the storage medium.

According to an embodiment of the disclosure, a method according to the various embodiments described above may be provided included a computer program product. The computer program product may be exchanged between a seller and a purchaser as a commodity. The computer program product may be distributed in a form of a machine-readable storage medium (e.g., a compact disc read only memory (CD-ROM)), or distributed online through an application store. In the case of online distribution, at least a portion of the computer program product may be stored at least temporarily in the storage medium such as a server of a manufacturer, a server of an application store, or a memory of a relay server, or temporarily generated.

Each of the elements (e.g., a module or a program) according to various embodiments described above may be configured as a single entity or a plurality of entities, and a portion of sub-elements of the above-mentioned sub-elements may be omitted, or other sub-elements may be further included in the various embodiments. Alternatively or additionally, a portion of the elements (e.g., modules or programs) may be integrated into one entity to perform the same or similar functions performed by each of the relevant elements prior to integration. Operations performed by a module, a program, or another element, in accordance with various embodiments, may be executed sequentially, in a parallel, repetitively, or in a heuristic manner, or at least a portion of the operations may be executed in a different order, omitted, or a different operation may be added.

While the disclosure has been illustrated and described with reference to example embodiments thereof, it will be understood that the embodiments are intended to be illustrative, not limiting. It will be understood by those skilled in the art that various changes in form and details may be made therein without departing from the true spirit and full scope of the disclosure, including the appended claims and their equivalents. Therefore, the scope of various embodiments of the disclosure should be interpreted as encompassing all modifications or variations derived based on the technical spirit of various embodiments of the disclosure in addition to the embodiments disclosed herein.

What is claimed is:

1. A vacuum cleaner comprising:
memory storing instructions;
a power part comprising a rechargeable battery;
a suction motor configured to be driven by power supplied by the power part to suction debris;
a debris container configured to store the debris that is suctioned by the suction motor;
a charging terminal configured to be connectable to an external charging device that is configured to charge the rechargeable battery; and
at least one processor comprising processing circuitry,
wherein the instructions, when executed individually or collectively by the at least one processor, cause the vacuum cleaner to:
perform a charging function in a first mode by supplying a battery current of a threshold strength to the rechargeable battery,
obtain, in a state of performing the charging function in the first mode, a first voltage of the charging terminal of the vacuum cleaner and a second voltage of a charging terminal of the external charging device,
identify whether a charging error has occurred based on the first voltage and the second voltage,
based on identifying the charging error has not occurred, obtain a battery voltage of the rechargeable battery in the state of performing the charging function in the first mode, and
based on the battery voltage being greater than or equal to a threshold value, performing the charging function in a second mode by maintaining the battery voltage within a threshold range that corresponds to the threshold value.

2. The vacuum cleaner of claim 1, wherein the instructions, when executed by the at least one processor individually or collectively, cause the vacuum cleaner to:
based on identifying the charging error has occurred, stop performing the charging function in the first mode, and
wherein the charging error comprises an error due to a charging abnormality between the charging terminal of the vacuum cleaner and the charging terminal of the external charging device.

3. The vacuum cleaner of claim 1, wherein the instructions, when executed individually or collectively by the at least one processor, cause the vacuum cleaner to:
obtain a difference value between the first voltage and the second voltage, and
identify whether the charging error has occurred based on the difference value.

4. The vacuum cleaner of claim 3, wherein the instructions, when executed by the at least one processor individually or collectively, cause the vacuum cleaner to:
continue performing the charging function in the first mode based on the difference value being less than or equal to a first threshold value, and
based on the difference value exceeding a second threshold value which is greater than the first threshold value, identify that the charging error has occurred.

5. The vacuum cleaner of claim 4, wherein the instructions, when executed by the at least one processor individually or collectively, cause the vacuum cleaner to:
based on the difference value exceeding the first threshold value and being less than or equal to the second threshold value, identify whether the charging error has occurred by re-obtaining the first voltage and the second voltage.

6. The vacuum cleaner of claim 1, wherein the instructions, when executed by the at least one processor individually or collectively, cause the vacuum cleaner to:
based on identifying the charging error has occurred, stop performing the charging function in the first mode by controlling a switch of the power part to be an off state.

7. The vacuum cleaner of claim 1, further comprising:
a display; and
a speaker,
wherein the instructions, when executed by the at least one processor individually or collectively, cause the vacuum cleaner to:
based on identifying the charging error has occurred, control the display to display an error user interface (UI) indicating the charging error, or control the speaker to output a sound corresponding to the error UI.

8. The vacuum cleaner of claim 1, further comprising:
a communication interface,
wherein the instructions, when executed by the at least one processor individually or collectively, cause the vacuum cleaner to:
activate the communication interface based on the charging terminal of the vacuum cleaner being in contact with the charging terminal of the external charging device,
request, through the communication interface, a response from the external charging device,
identify that an error has occurred based on a response signal not being received from the external charging device through the communication interface, and
output an error user interface (UI) to indicate that the error has occurred.

9. The vacuum cleaner of claim 8, wherein the instructions, when executed by the at least one processor individually or collectively, cause the vacuum cleaner to:
perform the charging function in the first mode based on the response signal being received from the external charging device through the communication interface.

10. The vacuum cleaner of claim 1, wherein the first mode corresponds to a constant current (CC) mode configured to maintain a strength of the battery current at the threshold strength, and
wherein the second mode corresponds to a constant voltage (CV) mode configured to maintain the battery voltage within the threshold range based on the threshold value.

11. A control method of a vacuum cleaner comprising a power part which comprises a rechargeable battery, a suction motor configured to be driven by power supplied by the power part to suction debris, a debris container configured to store the debris that is suctioned by the suction motor, and a charging terminal configured to be connectable to an external charging device that is configured to charge the rechargeable battery, the control method comprising:
performing a charging function in a first mode by supplying a battery current of a threshold strength to the rechargeable battery;
obtaining, in a state of performing the charging function in the first mode, a first voltage of the charging terminal of the vacuum cleaner and a second voltage of a charging terminal of the external charging device;
identifying whether a charging error has occurred based on the first voltage and the second voltage;
based on identifying that the charging error has occurred, stop performing the charging function in the first mode;
based on identifying the charging error has not occurred, obtaining a battery voltage of the rechargeable battery in the state of performing the charging function in the first mode; and
based on the battery voltage being greater than or equal to a threshold value, performing the charging function in a second mode by maintaining the battery voltage within a threshold range that corresponds to the threshold value.

12. The method of claim 11, wherein the charging error comprises an error due to a charging abnormality between the charging terminal of the vacuum cleaner and the charging terminal of the external charging device.

13. The method of claim 11, wherein the identifying whether the charging error has occurred comprises:
obtaining a difference value between the first voltage and the second voltage, and
identifying whether the charging error has occurred based on the difference value.

14. The method of claim 13, wherein the identifying whether the charging error has occurred comprises:
continue performing the charging function in the first mode based on the difference value being less than or equal to a first threshold value, and
based on the difference value exceeding a second threshold value which is greater than the first threshold value, identifying that the charging error has occurred.

15. The method of claim 14, wherein the identifying whether the charging error has occurred further comprises:
based on the difference value exceeding the first threshold value and being less than or equal to the second threshold value, identifying whether the charging error has occurred by re-obtaining the first voltage and the second voltage.

16. An electronic device comprising:
memory storing instructions;
a power part comprising a rechargeable battery;
a charging terminal configured to be connectable to an external charging device that is configured to charge the rechargeable battery; and
at least one processor comprising processing circuitry,
wherein the instructions, when executed by the at least one processor individually or collectively, cause the electronic device to:
perform a charging function in a first mode by supplying a battery current of a threshold strength to the rechargeable battery,
obtain, in a state of performing the charging function in the first mode, a first voltage of the charging terminal of the electronic device and a second voltage of a charging terminal of the external charging device,
identify whether a charging error has not occurred based on the first voltage and the second voltage,
based on identifying the charging error has occurred, obtain a battery voltage of the rechargeable battery in the state of performing the charging function in the first mode, and
based on the battery voltage being greater than or equal to a threshold value, performing the charging function in a second mode by maintaining the battery voltage within a threshold range that corresponds to the threshold value.

17. The electronic device of claim 16, wherein the instructions, when executed by the at least one processor individually or collectively, cause the electronic device to:
based on identifying the charging error has occurred, stop performing the charging function in the first mode, and
wherein the charging error comprises an error due to a charging abnormality between the charging terminal of the electronic device and the charging terminal of the external charging device.

18. The electronic device of claim 16, wherein the instructions, when executed by the at least one processor individually or collectively, cause the electronic device to:
obtain a difference value between the first voltage and the second voltage, and
identify whether the charging error has occurred based on the difference value.

19. The electronic device of claim 18, wherein the instructions, when executed by the at least one processor individually or collectively, cause the electronic device to:
continue performing the charging function in the first mode based on the difference value being less than or equal to a first threshold value, and
based on the difference value exceeding a second threshold value which is greater than the first threshold value, identify that the charging error has occurred.

20. The electronic device of claim 19, wherein the instructions, when executed by the at least one processor individually or collectively, cause the electronic device to:
based on the difference value exceeding the first threshold value and being less than or equal to the second threshold value, identify whether the charging error has occurred by re-obtaining the first voltage and the second voltage.
